(19) United States
(12) Patent Application Publication
(10) Pub. No.: US 2026/0319044 A1
(43) Pub. Date: Oct. 15, 2026

(54) AMPLITUDE MODULATION OF RADIOFREQUENCY PULSES FOR B1-SELECTIVE EXCITATION IN MAGNETIC RESONANCE IMAGING

(71) Applicant: Regents of the University of Minnesota, Minneapolis, MN (US)

(72) Inventors: Michael Garwood, Minneapolis, MN (US); Saurin Kantesaria, Minneapolis, MN (US); Efraín TORRES, Minneapolis, MN (US)

(21) Appl. No.: 19/640,004

(22) Filed: Apr. 6, 2026

Related U.S. Application Data
(60) Provisional application No. 63/783,921, filed on Apr. 4, 2025.

(51) Int. Cl. G01R 33/483; G01R 33/36; G01R 33/54

(52) U.S. Cl. CPC G01R 33/4831; G01R 33/3607; G01R 33/543

(57) ABSTRACT

A method for magnetic resonance imaging of a sample is provided herein. The method includes applying a static magnetic field to the sample and, in the presence of the static magnetic field, applying a radiofrequency (RF) pulse. The RF pulse includes a first RF field component along a first spatial axis and a second RF field component along a second spatial axis. The first RF field component is doubly amplitude modulated using a first modulation function and a second modulation function that is a function of a phase of the RF pulse. The RF pulse selectively excites a portion of the sample. The method further includes measuring a magnetic resonance signal produced by the excited portion of the sample.

### CROSS-REFERENCE TO RELATED APPLICATIONS

This application claims the benefit of U.S. Provisional Patent Application Ser. No. 63/783,921, filed on Apr. 4, 2025, and entitled “AMPLITUDE MODULATION OF RADIOFREQUENCY PULSES FOR B1-SELECTIVE EXCITATION IN MAGNETIC RESONANCE IMAGING,” which is herein incorporated by reference in its entirety.

### STATEMENT REGARDING FEDERALLY SPONSORED RESEARCH

This invention was made with government support under EB025153, EB033347, and EB027061 awarded by the National Institutes of Health. The government has certain rights in the invention.

### BACKGROUND

Magnetic resonance imaging (MRI) scanners are typically bulky and expensive to purchase and operate. The most expensive component is the magnet producing the static field (B₀). The second most costly component is typically the B₀-gradient system, which can account for as much as ~30% of the total system cost. In addition, B₀ gradient systems require expensive gradient amplifiers, infrastructure costs from power and cooling, and a reliable source of electrical power and chilled water to operate. Gradient coils typically include multiple cylinders with copper windings to generate linear magnetic field gradients along the X, Y, and Z axes, occupying precious bore space. Moreover, when switched on and off quickly, they can result in peripheral nerve stimulation and eddy currents in surrounding conductive components of the scanner, which can degrade signal quality, and produce Lorentz forces generating loud noise which increases patient anxiety.

Radiofrequency (RF) gradients are an exciting alternative to B₀ gradients as they rely on alternating magnetic field gradients produced by the RF coils themselves, eliminating the need for B₀ gradients. This not only saves bore space but also results in quiet scans. Furthermore, RF gradients can be switched on the order of microseconds as opposed to hundreds of microseconds, opening new possibilities for pulse sequence design. Minimal to no cooling is needed for these coils, reducing long term costs as well. However, there is a lack of pulse sequences capable of slice selection without B₀ gradients, particularly methods that are robust to B₀ and B₁ inhomogeneity.

### SUMMARY OF THE DISCLOSURE

According to an aspect of the present disclosure, a method for magnetic resonance imaging of a sample is provided. The method includes applying a static magnetic field to the sample. In the presence of the static magnetic field, a radiofrequency (RF) pulse is applied. The RF pulse includes a first RF field component along a first spatial axis and a second RF field component along a second spatial axis. The first RF field component is doubly amplitude modulated using a first modulation function and a second modulation function that is a function of a phase of the RF pulse. The RF pulse selectively excites a portion of the sample. The method also includes measuring a magnetic resonance signal produced by the excited portion of the sample.

According to another aspect of the present disclosure, a method for magnetic resonance imaging of a sample is provided. The method includes applying a static magnetic field to the sample. In the presence of the static magnetic field, an adiabatic radiofrequency pulse is applied to generate a spatially varying radiofrequency magnetic field in a first direction and a temporally varying radiofrequency field in a second direction. The temporally varying radiofrequency field selectively excites a portion of the sample.

### BRIEF DESCRIPTION OF THE DRAWINGS

Various objects, features, and advantages of the disclosed subject matter can be more fully appreciated with reference to the following detailed description of the disclosed subject matter when considered in connection with the following drawings, in which like reference numerals identify like elements.

FIG. 1A shows an example setup of radiofrequency coils that can be used in accordance with the present disclosure.

FIG. 1B demonstrates an example slice selective excitation achieved using the methods of the present disclosure.

FIG. 1C shows an example hyperbolic secant pulse and corresponding frequency sweep bandwidth.

FIG. 2A shows an example of a linearly polarized magnetic field decomposed into two counterrotating fields.

FIG. 2B shows an example of a spin rotation in the first rotating frame.

FIG. 2C shows an example of a spin rotation in the second rotating frame.

FIG. 3A shows an example amplitude modulation of a chirp pulse for illustrative purposes.

FIG. 3B shows an example of a spin's rotation corresponding to the pulse shown in FIG. 3A.

FIG. 4 shows an example of interleaved B₁ and B₂ fields.

FIG. 5 shows an example of an interleaved selective pulse.

FIG. 6 shows an example inversion of a spin during an interleaved B₁ selective pulse in the first rotating frame.

FIG. 7 shows a comparison of hyperbolic secant pulses for use in slice selection.

FIG. 8 shows a comparison of hyperbolic secant pulses with varying A values.

FIG. 9 shows an example pulse sequence that can be used to refocus spins in the Rabi dimension.

FIG. 10A shows example simulation results demonstrating magnetization in the first rotating frame for slice selection.

FIG. 10B shows example simulation results demonstrating magnetization components for slice selection.

FIG. 10C shows additional example simulation results demonstrating magnetization in the first rotating frame for slice selection.

FIG. 10D shows additional example simulation results demonstrating magnetization components for slice selection.

FIG. 11A shows example simulation results demonstrating a set up for slice inversion with a single coil.

FIG. 11B shows example simulation results demonstrating inversion of a slice with a single coil.

FIG. 12 shows example simulation results demonstrating inversion of a slice with a single coil for varying experimental parameters.

FIG. 13 shows example simulation results that demonstrate excitation pulse shapes and magnetization profiles for low flip-angle AM_{HS1} using a single coil, with and without refocusing lobes and RF scaling.

FIG. 14A shows example simulation results corresponding to an AM_{HS1} pulse.

FIG. 14B shows additional example simulation results corresponding to an AM_{HS1} pulse.

FIG. 14C shows example simulation results corresponding to an SLR pulse.

FIG. 14D shows additional example simulation results corresponding to an SLR pulse.

FIG. 15A shows an example implementation of a double spin echo pulse sequence.

FIG. 15B shows an example of a rotary echo produced by the pulse sequence of FIG. 15A in simulation.

FIG. 15C shows an example slab excitation produced by the pulse sequence of FIG. 15A in simulation.

FIG. 16A shows an example implementation of a double spin echo pulse sequence.

FIG. 16B shows experimental results of slice selection using a surface coil corresponding to the pulse sequence of FIG. 16A.

FIG. 16C shows additional experimental results of slice selection using a surface coil corresponding to the pulse sequence of FIG. 16A.

FIG. 17 shows example simulation results.

FIG. 18 shows example experimental results.

FIG. 19 shows additional example experimental results.

FIG. 20 shows additional example experimental results.

FIG. 21 shows additional example experimental results.

FIG. 22A illustrates an excitation slice profile generated using a two-coil setup with a subadiabatic AM_{HS1} pulse.

FIG. 22B illustrates an excitation slice profile generated using a one-coil setup with a subadiabatic AM_{HS1} pulse.

FIG. 23A demonstrates an AM_{HS1} pulse as a BIR-4 pulse using a single coil, two coils, and two coils plus a z-coil at varying flip angles.

FIG. 23B illustrates simulated magnetization components M_{xy} sampled along the B₁ gradient at the end of the BIR-4 AM_{HS1} pulse illustrated in FIG. 23A.

FIG. 24 illustrates AM_{HS1} with B_{1y} refocusing lobes and 2-step phase-cycle using a single coil.

FIG. 25 is a block diagram of an example magnetic resonance imaging (“MRI”) system that can implement the methods described in the present disclosure.

FIG. 26A shows in vivo experimental results produced using an example implementation of the described system and method.

FIG. 26B shows additional in vivo experimental results produced using an example implementation of the described system and method.

FIG. 27A shows an example simulation setup for testing AM_{HS1} pulses applied on a compact, low-field scanner.

FIG. 27B shows example simulation results using the setup shown in FIG. 27A.

FIG. 28 shows example simulation results with and without phase modulation shape function scaling.

FIG. 29 provides a flowchart setting forth steps of an example process for MRI with B1-selective excitation.

### DETAILED DESCRIPTION

Before any aspects of the present disclosure are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

The following discussion is presented to enable a person skilled in the art to make and use embodiments of the invention. Various modifications to the illustrated embodiments will be readily apparent to those skilled in the art, and the generic principles herein can be applied to other embodiments and applications without departing from embodiments of the invention. Thus, embodiments of the invention are not intended to be limited to embodiments shown but are to be accorded the widest scope consistent with the principles and features disclosed herein. The following detailed description is to be read with reference to the figures, in which like elements in different figures have like reference numerals. The figures, which are not necessarily to scale, depict selected embodiments and are not intended to limit the scope of embodiments of the invention. Skilled artisans will recognize the examples provided herein have many useful alternatives and fall within the scope of embodiments of the invention.

One of the first methods to implement the idea of spatial encoding with RF gradients was Hoult's rotating frame zeugmatography. While it established a baseline for other RF encoding methods, this method requires unreasonably large RF gradient strengths to produce images. This results in a high specific absorption ratio (SAR) and therefore is not practical for patient scanning.

Other methods, such as B₁-selective pulses (including Hoult's rotating frame pulses, Shinnar-Le-Roux-optimized (SLR), SLR-optimized with Bloch-Siegert shift, and so forth), Transmit Array Spatial Encoding (TRASE), and Frequency-modulated Rabi Encoded Echoes (FREE) have since built off Hoult's work to move towards lower cost MRI without B₀ gradients. Of these, only three, rotating frame zeugmatography, TRASE, and B₁-selective pulses, can perform slice selection, an important method needed for most mainstay sequences of clinical MRI. FREE and TRASE acquire one data point per acquisition and therefore require multi-shot or multi-echo acquisitions for localization. As such, they may not be ideal options for slice selection. B₁-selective pulses are then the most practical but are limited by high SAR and sensitivity to resonance offset, Ω=ω₀=−ω_{c}≠0, where ω_{c} is the carrier frequency and ω₀ is the Larmor frequency.

Hoult's method uses two RF fields, B₁ₓ and B_{1y}, which respectively serve the same purpose as B₁- and B₀-gradient fields in conventional MRI. B₁ is applied uniformly over the object, whereas B_{1y}(r), is applied as a gradient in direction r to create a continuum of nutation frequencies (aka Rabi frequencies). A band of these Rabi frequencies can be excited selectively by B₁ₓ. Originally, B₁ₓ was applied at a constant frequency. However, one major obstacle present in RF-encoded MRI is the presence of both B₀ and B₁ magnetic field inhomogeneity. This is especially the case for low-cost, compact scanners being targeted towards specific anatomical regions. Thus, off-resonance sensitivity is an important consideration for new methods.

Adiabatic pulse sequences, such as the hyperbolic secant (HS) family of pulses, are robust to off resonance as they produce a frequency sweep that sequentially tips spins within a specified bandwidth. One may be tempted to simply apply adiabatic pulses, such as the HS1 pulse, to rotating frame zeugmatography, but SAR concerns remain. Thus, the present disclosure provides systems and methods to provide selective excitation of a slice or slab without the need for B₀ gradients that are typically needed for slice selection. As will be described, amplitude-modulation of an adiabatic pulse, such as a hyperbolic secant (HS1) pulse, produces a frequency sweep of one of its counterrotating components. This can be used to selectively excite a band of frequencies when an RF field is applied as a gradient to an object Enabling slice selection without B₀ gradients advantageously allows for faster gradient switching, silent scans, and no eddy currents. Moreover, low cost and portable MRI systems with no B₀ gradients can build off this pulse to recreate widely used sequences of clinical MRI.

In B₁-selective rotating frame imaging, two RF fields, which may be referred to as B₁ₓ and B_{1y}, can be used in place of B₁ and a B₀ gradient, respectively. B_{1y}(r) is applied as an RF gradient in the direction r to create a continuum of nutation frequencies (aka Rabi frequencies) and a band of Rabi frequencies can be selectively excited with a uniform B₁ₓ. For example, B_{1y} may be designed as a square pulse or an adiabatic full passage pulse, while B₁ₓ may be a slice-selective amplitude- and phase-modulated pulse that selectively excites a slice or slab in space.

Careful selection of B₁ₓ as an amplitude modulated (AM) adiabatic pulse can allow for resilience to B₁ and B₀ inhomogeneity to be achieved. As one non-limiting example, a hyperbolic secant (HS) pulse, such as an HS1 pulse, can be used. The present disclosure provides examples of simulation and experimental results that demonstrate the slice inversion profile and resilience to B₀ and B₁ inhomogeneity achieved using an AM HS1 pulse produced by surface coils on water phantoms. In some implementations, the pulse can be applied in a double spin echo to produce rotary echoes. The present disclosure also provides a method for achieving excitation with lower flip angles (e.g., <180°), which can be compatible with many modern pulse sequences that take advantage of low flip angles and the ability to perform B₁-mapping across the sample region of interest for image reconstruction. For arbitrary flip angles (e.g., θ<90°, 90°<θ<180°), a correction can be applied to produce an even slice profile.

To achieve spatially selective excitation, two B₁ fields are applied, which will be referred to as B₁ₓ and B_{1y}, or alternatively B₂(t) and B₁(t), in the present disclosure. To understand how slice selection is achieved, a 1D case will be examined in which a series of spins positioned along the y-axis are initially aligned in the z direction. An alternating magnetic field, B_{1y}, can be applied along the sample y-axis at the Larmor frequency:

$${ω}_{0} = γ {B}_{0}$$

where γ is the proton gyromagnetic ratio and B₀ is the applied static magnetic field along the z-axis. In the first rotating frame (x′, y′, z′), the RF field gradient, B_{1y}, which is spatially-varying, is arbitrarily oriented along the y′-axis. This causes the proton spins M along the gradient to nutate at frequencies proportional to the magnitude of B_{1y}. Thus, the Rabi frequency of a magnetization vector M varies with position (r)

$${ω}_{1 y} ( r ) = γ {B}_{1 y} ( r )$$

In some implementations, a separate orthogonal field can be applied simultaneously along the x-axis, B₁ₓ, which is homogenous over the object at the nutation (Rabi) frequency at the slice center, ω_{1y}(r_{center}). With this, a band of nutating M vectors are tipped out of their nutation around B_{1y}, and thus, are selectively excited. In some implementations, the carrier frequency of B₁ₓ can be set to ω₀, while the amplitude of B₁ₓ is sinusoidally modulated at frequency ω_{1y}(r_{center}). This results in a net frequency of ω₀±ω_{1y}(r_{center}).

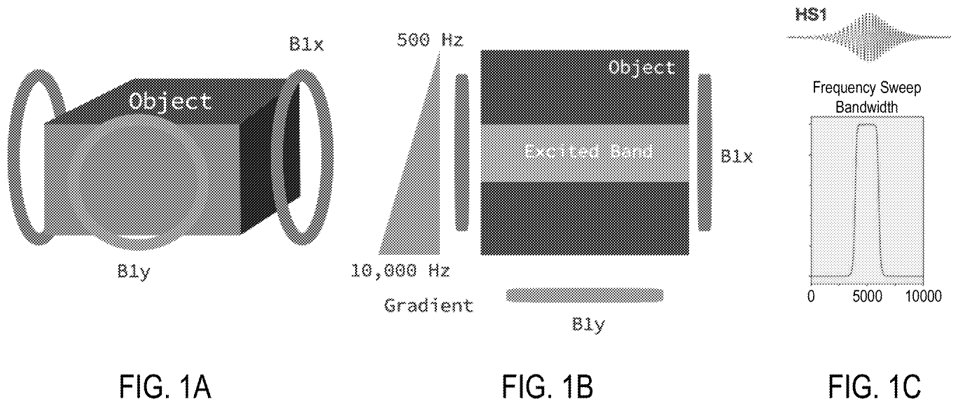

In some implementations of the described method, the frequency of B₁ₓ can be varied (e.g., continuously) to create a frequency-swept pulse in the second rotating frame, as will be described further below. This pulse sweeps through Rabi frequencies of interest to sequentially tip spins, similar to how HS1 tips a band of Larmor frequencies in the first rotating frame. In the present disclosure, this B₁-selective pulse may be referred to as AM_{HS1}. The HS1 pulse is provided as an example; however, other frequency- and amplitude-modulated pulses can be used as well, such as adiabatic pulses, HSn pulses, chirp pulses, composite pulses (e.g., BIR-4), and so forth. As a non-limiting example, FIG. 1 illustrates this with the use of two RF coils. However, the method may also be implemented with other coil arrangements. For example, a single coil implementation will also be described further below.

The described selectivity can be explained by moving from the typical first rotating frame, which rotates at frequency ω₀ about the z-axis, to a second frame rotating about the y′-axis at or near the nutation frequency ω_{1y}(r) within this first frame, which is denoted by ′. This can be referred to as the second rotating frame, which is denoted by ″. Transforming from the laboratory frame to the first rotating frame produces a fictitious field along the z′-axis that progressively diminishes as the carrier frequency approaches ω₀. Similarly, moving from the first rotating frame to the second rotating frame rotating with

$${ω}_{1 x}^{+} ( or {ω}_{1 x}^{-} )$$

causes B_{1y} along y′=y″ to disappear when applied on resonance (at the nutation frequency ω_{1y}(r)). Likewise, an off-resonance field exists along the y′-axis if

$${ω}_{1 x}^{+}$$

is applied off resonance; that is, when

$${ω}_{1 x}^{+} \neq {ω}_{1 y} ( r ) .$$

B₁ₓ can be carefully chosen as an adiabatic pulse, such as an HS1 pulse to excite a band of frequencies, as shown in FIGS. 1A-1C. B₁-selective rotating frame imaging is demonstrated in FIGS. 1A-1C using an adiabatic amplitude modulated HS1 pulse as a non-limiting example, referred to as “AM_{HS1}”. In FIG. 1A, an object or tissue is positioned with B₁ₓ and B_{1y} coils in space. In some implementations, the RF coils may include surface coils. The coils may include two sets of RF coils (e.g., a pair of coils associated with B₁ₓ and a coil associated with B_{1y}), a single RF surface coil combining the x and y components into the real and imaginary components of the same coil, or three sets of RF coils (e.g., a pair of coils associated with B₁ₓ, B_{1y}, and a separate field B_{1z} along the z-axis, such as a field that is equivalent to B₁ₓ shifted by 90°). Similarly, this could also involve the production of B₁ₓ and B_{1y} fields through a parallel transmit system with many coils to improve gradient homogeneity and allow for the potential of radial scanning. These RF coil sets may be arranged orthogonally or nearly orthogonally (e.g., 80°-110°) in space, as shown in FIG. 1A. FIG. 1B shows a top-down view of an object within a spatially homogeneous field that is denoted by B₁ₓ and a spatial gradient field from 0-10000 Hz that is denoted by B_{1y}. FIG. 1C shows how B₁ₓ is applied as an HS1 pulse with a frequency sweep from ~3000-6000 Hz, matching the object excited band shown in FIG. 1B. As demonstrated, B₁ₓ excites a band of spins along the B_{1y} gradient when applied as an HS1 pulse.

With this non-limiting example 2-coil setup, the effective field can be derived in the second rotating frame as follows. The equation of motion in the laboratory frame (neglecting relaxation) is

$$\frac{d M}{dt} = γ M \times B$$

A transformation to a frame ([x′, y′, z′]) rotating at frequency ω about z is then

$$\frac{\partial {M}^{′}}{\partial t} = \frac{d M}{d t} - M \times ω = M \times ( γ {B}_{0} - ω )$$

$$where$$

$${B}_{e f f}^{′} = ( {B}_{0} - \frac{ω}{γ} ) \text{?}$$

is the effective field in this so-called “first” rotating frame.

$${B}_{e f f}^{′}$$

is the familiar off-resonance field. A second rotation about the y′ axis at frequency

$${ω}_{1}^{′}$$

results in a doubly rotating frame ([x″, y″, z″]),

$$\frac{\partial {M}^{″}}{\partial t} = \frac{{dM}^{′}}{d t} - {M}^{′} \times {ω}_{1}^{′} = {M}^{′} \times ( γ {B}_{eff}^{′} - {ω}_{1}^{′} )$$

where the effective field is

$${B}_{eff}^{″} ( t ) = {B}_{eff}^{′} - \frac{{ω}_{1}^{′}}{γ} = {B}_{eff}^{′} ( cos ( {ω}_{1}^{′} t ) \text{?} - sin ( {ω}_{1}^{′} t ) \text{?} ) - ( \frac{{ω}_{1}^{′}}{γ} ) \text{?} .$$

For more straightforward pulse sequence design and simulation, this equation can be expressed in terms of unit vectors in the first rotating frame as

$${B}_{eff}^{″} ( t ) = {B}_{eff}^{′} \text{?} - ( \frac{{ω}_{1}^{′}}{γ} ) \text{?}$$

giveny [symbol] = [symbol] . This simplification can be made as [symbol] , when observed in the second rotating frame, rotates in the x″z″-plane at −

$${ω}_{1}^{′} .$$

Note that a finite resonance offset may lead to a potentially undesirable circularly-polarized interference from

$${B}_{eff}^{′} \text{?} .$$

To create a frequency-swept effective field in the second frame, two orthogonal time-dependent components of the field are needed. These are

$${B}_{1 x}^{″} ( t ) \text{?}$$

and a [symbol] vector representing a new resonance offset. This nutational offset is the difference between the amplitude modulation frequency of

$${B}_{1 x}^{″} ( t )$$

and the frequency of frame rotation,

$${ω}_{1}^{′} .$$

For simplicity, assume

$${B}_{eff}^{′} = 0 .$$

Similar to how B_{eff}(t) sweeps in the frequency-modulated frame, the effective field in the second frame is

$${B}_{eff}^{″} ( t ) = {B}_{1 x}^{″} ( t ) \text{?} - \frac{{ω}_{1}^{′} ( t )}{γ} \text{?} ,$$

$$where {ω}_{1}^{′} ( i )$$

is now variable in time to create this sweep.

As a non-limiting example, with a B₁-selective HS pulse, the amplitude of

$${B}_{1 x}^{″} ( t ) \text{?}$$

is a sech modulation and offset field

$${B}_{1 y}^{″} ( t ) \text{?}$$

is a tanh modulation. This is analogous to the frequency modulation that creates the fictitious field along z′ for a typical HS1 pulse in the frequency-modulated frame.

The AM_{HS1} pulse can be described as:

$${B}_{1 x}^{″} ( t ) = {B}_{1 x}^{max} {F}_{1} ( t )$$

$$where$$

$${F}_{1} ( t ) = sech ( \frac{2 β}{{T}_{p}} ( t - \frac{{T}_{p}}{2} ) )$$

$$and$$

$${B}_{1 y}^{″} ( t ) = \frac{2 π A}{γ} tanh ( \frac{2 β}{{T}_{p}} ( t - \frac{{T}_{p}}{2} ) )$$

is the maximum

$${B}_{1 x}^{″} ( t ) , {F}_{1} ( t )$$

is a normalized shape function, t is time, Tₚ is pulse duration, 2A is the frequency sweep bandwidth, and truncation factor β=arcsech(0.01).

Assuming

$${B}_{eff}^{′} = 0 ,$$

this second frame HS1 can adiabatically rotate a magnetization vector from y′ to −y′ (noting, again, y′=y″).

Implementation using a conventional MRI spectrometer may use a pulse driving function as

$${B}_{1 xz}^{′} ( t ) = {B}_{1 x}^{max} {F}_{1} ( t ) ( cos ( {ϕ}_{HS 1} ( t ) ) \text{?} + sin ( {ϕ}_{HS 1} ( t ) ) \text{?} ) ,$$

$$where$$

$${ϕ}_{HS 1} ( t ) = \frac{π R}{2 β} ln ( \frac{{B}_{1 x}^{max}}{{B}_{1 x}^{″} ( t )} )$$

is the time-dependent phase modulation function for B₁ₓ(t) that produces a time-dependent field along y″, R is the unitless time-bandwidth product,

$${B}_{1 y}^{″} ( t )$$

will become a gradient to allow for spatial selectivity.

As shown above,

$${B}_{1 xz}^{′} ( t )$$

is circularly polarized in the x′z′ plane. To create the z′ component of

$${B}_{1 xz}^{′} ( t ) ,$$

a z-coil capable of sweeping between ±A with amplitude

$$γ {B}_{1 x}^{max} / 2 π \underline{>} A$$

is needed. Because a z-coil is not typically available, in some implementations, a linearly-polarized driving function may be used as

$${B}_{1 x}^{′} ( t ) = {B}_{1 x}^{max} {F}_{1} ( t ) ( cos ( {ϕ}_{H S 1} ( t ) ) \text{?} ) ,$$

Because

$${B}_{1 x}^{′} ( t )$$

can be decomposed into two counterrotating fields,

$${B}_{1 x}^{′} ( t ) = \frac{{B}_{1 x}^{max} {F}_{1} ( t )}{2} ( ( cos ( {ϕ}_{H S 1} ( t ) ) \text{?} + sin ( {ϕ}_{H S 1} ( t ) ) \text{?} ) + ( cos ( {ϕ}_{H S 1} ( t ) ) \text{?} - sin ( {ϕ}_{H S 1} ( t ) ) \text{?} ) ) .$$

The oppositely-rotating component is neglected based on the rotating wave approximation, giving

$${B}_{1 x}^{′} ( t ) = \frac{{B}_{1 x}^{max} {F}_{1} ( t )}{2} ( cos ( {ϕ}_{H S 1} ( t ) ) \text{?} + sin ( {ϕ}_{H S 1} ( t ) ) \text{?} ) ,$$

Accordingly,

$${B}_{1 xz}^{′} ( t ) = 2 {B}_{1 x}^{′} ( t ) .$$

Of note, two amplitude-modulations occur simultaneously in AM_{HS1}. The first is the sech envelope from F₁(t), while the second is due to the phase modulation φ_{HS1}(t). This second modulation is fed into the amplitude-modulation function for

$${B}_{1 x}^{′} ( t ) ,$$

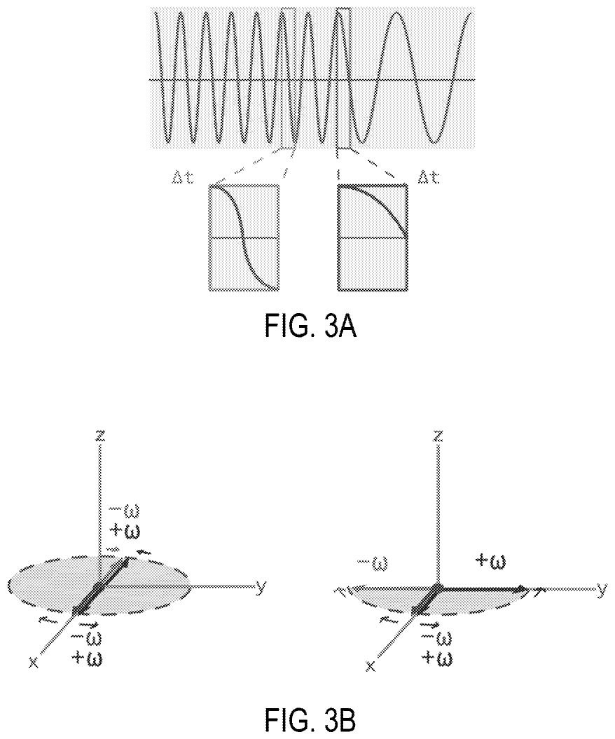

which forms the frequency sweep. This amplitude modulation is equivalent to two counterrotating fields that sweep at a varying rate in time, as shown in FIGS. 3A-3B.

As previously described, as in FIGS. 1A and 1B, two coils or coil sets can be used in some implementations. Consider a non-limiting example implementation, in which two RF coils produce

$${B}_{1 x}^{′} ( t ) and {B}_{1 y}^{′} ( t , r )$$

in the first rotating frame to create an AM_{HS1} pulse.

$${B}_{1 x}^{′} ( t )$$

corresponds to a homogenous coil over the object and

$${B}_{1 y}^{′} ( t , r )$$

corresponds to a coil producing a B₁ gradient

$${B}_{1 y}^{′} ( t , r )$$

can be a square pulse to simplify to

$${B}_{1 y}^{′} ( r ) .$$

The frequency sweep FM(t) can be given as the derivative of the phase modulation described above

$$FM ( t ) = \frac{d {ϕ}_{H S 1}}{dt}$$

The FM(t) function plays an important role in ensuring acceptable performance of any FM pulse. However, in some cases, implementation on MRI scanners may benefit from the use of modulated phases of the pulse, as described above. To shift a selected slice along the y-axis, the amplitude modulation of

$${B}_{1 x}^{′} ( t )$$

that is created by the phase modulation (φ_{HS1}) can be offset.

For the two-coil case, the total phase function modulating

$${B}_{1 x}^{′} ( t )$$

is

$${ϕ}_{tot} ( t ) = {ϕ}_{H S 1} ( t ) + {ϕ}_{off} ( t ) ,$$

where φ_{off}(t)=2πf_{off}t is a linear phase ramp calculated from the frequency offset f_{off} used to position the slice in Rabi frequency space. Accordingly,

$${B}_{1 x}^{′} ( t )$$

is doubly amplitude-modulated as

$${B}_{1 x}^{′} ( t ) = {B}_{1 x}^{m ax} {F}_{1} ( t ) cos ( {ϕ}_{tot} ( t ) )$$

As shown above, the first amplitude modulation is through the HS1 shape function, scaled to produce

$${B}_{1 x}^{ma x} {F}_{1} ( t ) ,$$

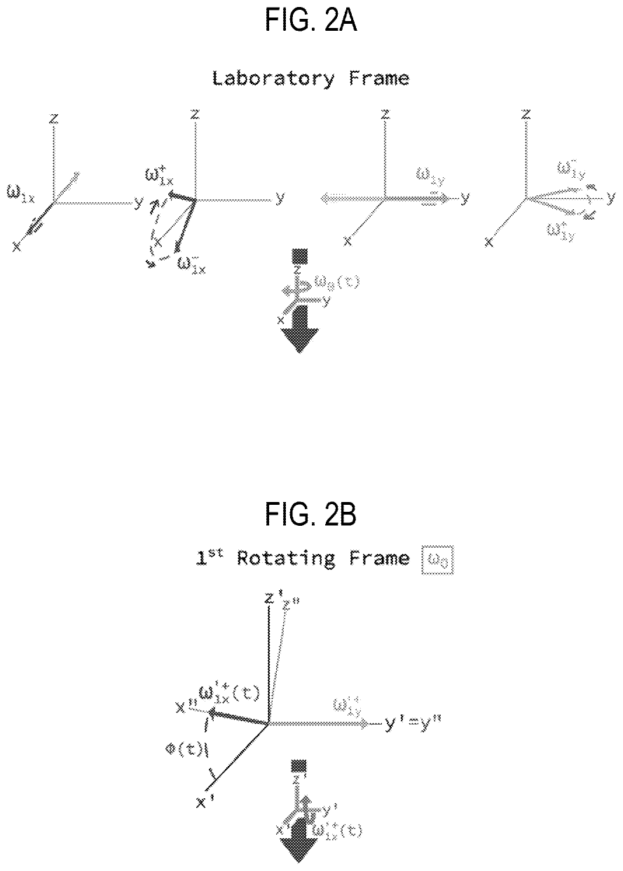

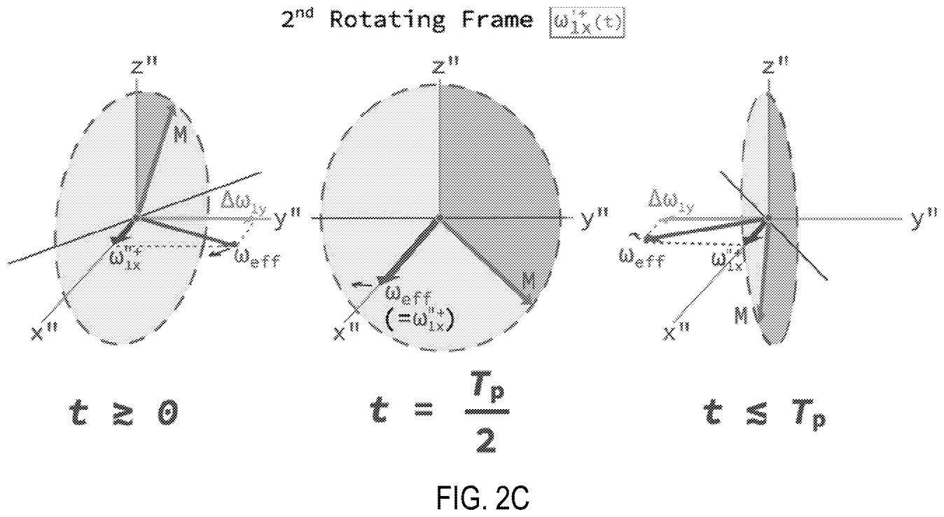

and the second amplitude modulation is from the phase modulation φₜₒₜ(t) used to create a frequency sweep with a slice offset. In some implementations, a cosine is used to initially align the first and second frames, as shown in FIGS. 2A-2C.

In some implementations, a single coil or coil set can be used, which may reduce hardware requirements and be more convenient to implement for imaging. As a non-limiting example, B₁ₓ and B_{1y} can be applied as the real and imaginary components of a single coil whose amplitude B_{G} and phase φ_{RF} are calculated from the two-coil fields, B₁ₓ and B_{1y}. The gradient of the single coil can be expressed as

$${B}_{G}^{′} ( t , r ) = {B}_{G} ( r ) {e}^{i {ϕ}_{R F} ( t )} ,$$

where the position-dependent scalar B_{G} describes the RF amplitude across the RF gradient of a single coil as

$${B}_{G} ( r ) := \sqrt{{( {B}_{1 x}^{m ax} ( r ) )}^{2} + {( {B}_{1 y}^{′} ( r ) )}^{2}} , where {B}_{1 x}^{m ax} ( r )$$

is the peak value of

$${B}_{1 x}^{′} ( t , r )$$

in time, and

$${B}_{1 y}^{′} ( r )$$

is a time-independent orthogonal component, both defined according to the two-coil equations above. The phase for the one-coil pulse φ_{RF}(t) (again with

$${B}_{1 x}^{′} and {B}_{1 y}^{′}$$

from the two-coil case) is

$${ϕ}_{R F} ( t ) = arctan ( \frac{{B}_{1 y}^{′} ( {r}_{center} )}{{B}_{1 x}^{′} ( t , {r}_{center} )} ) .$$

For convenience

$${B}_{1 x}^{′} and {B}_{1 y}^{′}$$

can be described according to vectors having units of frequency

$${ω}_{1 x}^{′} ( t ) = γ {B}_{1 x}^{′} ( t ) \text{?}$$

$${ω}_{1 y}^{′} ( r ) = γ {B}_{1 y}^{′} ( r ) \text{?} .$$

Likewise, the RF amplitude scalar can be described as

$${ω}_{G}^{′} ( r ) = γ {B}_{G} ( r ) .$$

FIGS. 2A-2C illustrate how the field components form in different frames. In the doubly-rotating second frame that follows one of two counterrotating

$${ω}_{1 x}^{′} ( t )$$

components,

$${ω}_{1 x}^{′ +} ( t ) ( or {ω}_{1 x}^{′ -} ( t ) ) ,$$

the component along y″,

$${ω}_{1 y}^{′} ,$$

disappears when

$${ω}_{1 x}^{′ +} ( t )$$

is the Rabi frequency. Likewise, a nutational off-resonance field,

$${Δω}_{1 y} ( t ) = ( {ω}_{1 x}^{′ +} ( t ) - {ω}_{1 y}^{′} ) \text{?} ,$$

exists along y″ when

$${ω}_{1 x}^{′ +} ( t ) \neq {ω}_{1 y}^{′} .$$

Due to the frequency sweep, an effective field vector,

$${ω}_{eff} ( t ) = {ω}_{1 x}^{′ +} ( t ) + Δ {ω}_{1 y} ( t ) ,$$

traces from −y″ to +y″, as shown in FIGS. 2A-2C.

As will be demonstrated later, to avoid out of band excitations and reduce overall SAR, a field that is 90° out of phase with B₁ₓ to produce a fully circularly-polarized x′z′ field can be added.

While a fully adiabatic AM_{HS1} pulse can invert spins completely within its bandwidth for both two- and one-coil setups, a sub-adiabatic pulse with a single coil can be used to produce a slice with varying flip angle because

$${B}_{1 x}^{′}$$

varies spatially, in this scenario, the pulse will leave some magnetization along the x′-axis. This dispersive component can be subtracted by cycling the initial phase between 0° and 180° in some implementations. However, an undesirable effect may remain due to the dependence of

$${B}_{1 x}^{max}$$

on spatial position. To correct for this, in some implementations, the pulse amplitude can be scaled by a normalized version of the frequency sweep FM(t),

$${FM}_{norm} ( t ) = \frac{- FM ( t )}{\frac{{ω}_{1 y}^{′} ( {r}_{center} )}{2 π} + \frac{R}{2 {T}_{p}}} ,$$

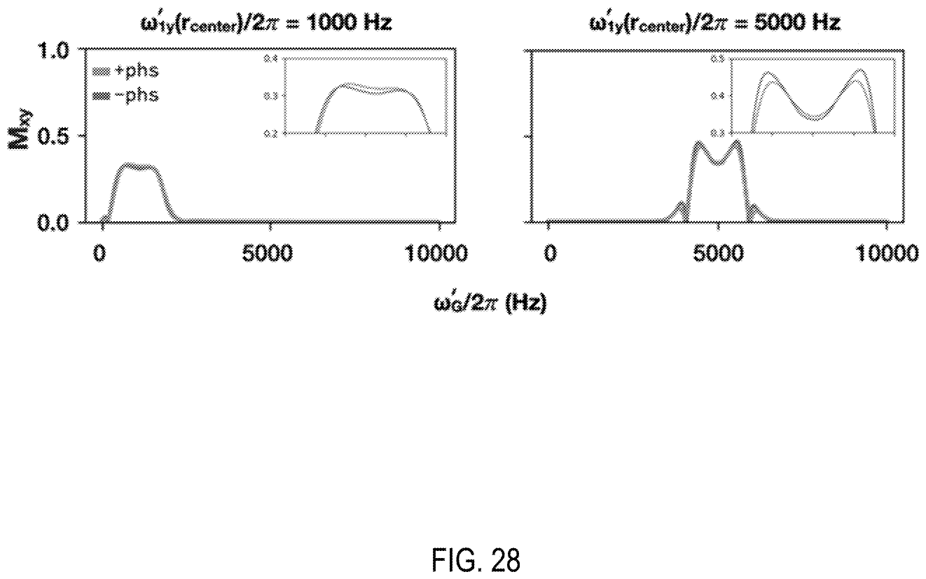

and the phase-modulation φ_{HS1}(t)

$${ϕ}_{norm} ( t ) = \frac{{ϕ}_{HS 1} ( t ) - min {ϕ}_{HS 1} ( t )}{max {ϕ}_{HS 1} ( t ) - min {ϕ}_{HS 1} ( t )} ,$$

$$as$$

$${F}_{{1}_{cor}} ( t ) = {F}_{1} ( t ) {FM}_{norm} ( t ) {ϕ}_{norm} ( t ) ,$$

where FMₙₒᵣₘ(t) is the normalized frequency sweep, φₙₒᵣₘ(t) is the normalized phase-modulation, and F₁_{_{cor}}(t) is the corrected shape function. To keep the amplitude constant, F₁_{_{cor}}(t) is divided by its maximum. FMₙₒᵣₘ(t) reverses and scales the frequency sweep based on the maximum frequency attained within its bandwidth to provide an initial scaling of the shape function based on position within the B′₁ₓ gradient. For large bandwidth pulses, the center of the excitation profile curves downwards, as shown in FIG. 28, and thus, an extra minor correction is performed with the normalized phase-modulation #norm (t), which peaks at the center of the frequency sweep. Due to the sequential tipping of spins in the frequency sweep, correcting the shape function of B′₁ₓ in this manner increases the RF amplitude experienced by spins distal to the coil. FIG. 28 provides an experimental comparison of low flip angle slice profile for AM_{HS1} using a single coil with (+phs) and without (−phs) phase modulation shape function scaling for

$${ω}_{1 y}^{′} ( {r}_{center} ) / 2 π = 1000 Hz ( left )$$

$$and$$

$${ω}_{1 y}^{′} ( {r}_{center} ) / 2 π = 5000 Hz ( right ) .$$

Both of these excitations use the FM shape function scaling.

It is an aspect of the present disclosure to provide for double amplitude modulation of an RF pulse by applying a first modulation function to a first RF field component of the RF pulse to provide a first amplitude modulation and applying a second modulation function to the first component of the RF field to provide a second amplitude modulation. The second modulation function is a function of the total phase of the two B₁-field components: B₁ₓ and B_{1y}. The first modulation function can be any suitable amplitude modulation function. In the example described above, the first amplitude modulation is provided by a hyperbolic secant envelope from F₁(t), while the second amplitude modulation is provided by the phase modulation φ_{HS1}(t). This second modulation is fed into the overall amplitude modulation function for

$${B}_{1 x}^{′} ( t )$$

which forms the frequency sweep. This amplitude modulation is similar to two counterrotating fields that sweep at a varying rate in time, as illustrated in FIGS. 3A and 3B.

Referring again to FIGS. 2A-2C, B₁-selective rotating frame imaging vector diagrams for a single spin are illustrated. In FIG. 2A, a linearly polarized magnetic field is decomposed into two counterrotating fields. Here ω_{1y}(t) and ω₁ₓ(t) are decomposed onto counterrotating fields

$${ω}_{1 y}^{\pm } and {ω}_{1 x}^{\pm }$$

along the xz-plane (left) and xy-plane (right). In FIG. 2B,

$${ω}_{1 x}^{′ +} ( t ) and {ω}_{1 y}^{′ +}$$

are applied in the first rotating frame, rotating at ω₀ about the z-axis.

$${ω}_{1 y}^{+}$$

is locked to the y′-axis.

$${ω}_{1 x}^{+} ( t )$$

is locked in the x′z′ plane and rotates about the y′-axis. FIG. 2C shows the second frame rotating at

$${ω}_{1 x}^{+} ( t )$$

about the y′-axis. This removes the effect of

$${ω}_{1 y}^{+}$$

when applied on resonance and causes M to tip around

$${ω}_{1 x}^{+} .$$

### When

$${ω}_{1 x}^{+}$$

is applied off resonance, a fictitious field Δω_{1y} appears that changes the tipping experienced by M. Assuming the frequency sweep for AM_{HS1} is centered around the current isochromat, Δω_{1y} starts off large and oriented along the +y-axis (left), then decreases to 0 (middle), and grows back to the same size along the −y-axis (right). This produces a net field in the second rotating frame

$${ω}_{eff} ( t ) = {ω}_{1 x}^{′ +} ( t ) + Δ {ω}_{1 y} ( t )$$

in which M nutates around as it sweeps from right to left during the pulse.

It is important to recognize that there are two amplitude modulations happening simultaneously, which may be referred to as double amplitude modulation. The first is from the sech envelope in F₁(t), while the second is from the phase modulation φ_{HS1}(t). This second modulation is fed into the overall amplitude modulation function for B₁ₓ(t), which forms the frequency sweep. This amplitude modulation can be considered equivalent to two counterrotating fields that sweep at a varying rate in time, as demonstrated in FIGS. 3A-3B. In FIG. 3A, an amplitude modulation for a chirp pulse is shown in the xy-plane for illustrative purposes. Two time periods of length Δt are shown at earlier and later points within the chirp pulse. FIG. 3B shows how these chirp pulse segments can be decomposed into two counterrotating fields rotating at a variable amplitude modulation frequency. The instantaneous vector amplitudes at time Δt are ±ω with blue vectors indicating the initial position and red vectors indicating the final position within the sampled Δt.

In some implementations, the amplitude modulated slice-selective pulse, B₁ₓ, can be interleaved with the spatial gradient pulse, B_{1y}. In this case, B₁ₓ(t) is interleaved in between pulse segments of B_{1y}(t). B₁ₓ(t) can be designed with a phase-modulation function that ensures B₁ₓ(t) remains perpendicular to B_{1y}(t)'s B_{eff} field. As a result of the phase modulation function, B₁ₓ(t) remains perpendicular to the magnetization as it is being inverted by B_{1y}(t). B₁(t) thus selectively excites spins rotating at a Rabi frequency within the bandwidth of the B₁ₓ(t) slice profile. In the following discussion, B₁ₓ is referred to as B₂, while B_{1y} is referred to as B₁.

A comb function is defined as

$${III}_{T} ( t ) := {\sum }_{k = - ∞}^{∞} δ ( t - kT )$$

where T is the periodicity in seconds. The Fourier transformation repeats a Dirac function every ±n(T⁻¹), where n is an integer number. In a similar manner, a radio-frequency (RF) pulse is segmented into a periodic train of RF pulse segments with a spacing of τₙ,

$$\overline{{B}_{n}} ( t ) := {\sum }_{k = 0}^{N} {B}_{n} ( t - {k τ}_{n} )$$

N denotes the number of pulse segments, which are of length Δτₙ and made up of pulse elements of length Δtₙ. In the frequency domain, a spacing of τₙ creates side bands every ±n(τₙ⁻¹). Two periodic RF pulses, B̅₁̅(t) and B̅₂̅(t) are created. B̅₁̅(t)'s amplitude- and phase-modulation functions define an adiabatic full passage, while B̅₂̅(t)'s amplitude- and phase-modulation functions selectively excite in the Rabi dimension.

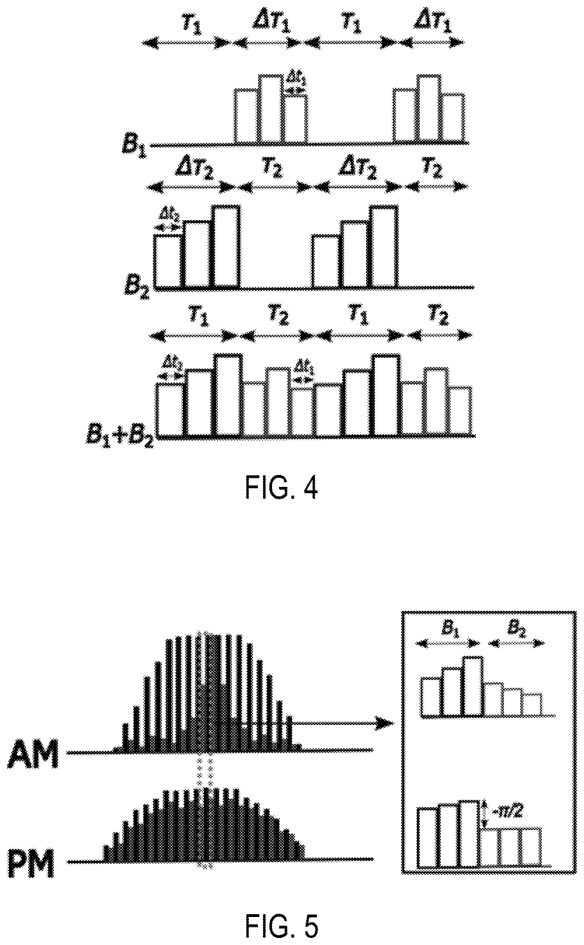

τ₁ and τ₂ define the periodicity of B̅₁̅(t) and B̅₂̅(t). τ₁ and τ₂ can be defined such that the pulses can be interleaved to create a continuous waveform, as shown in FIG. 4. B̅₂̅(t)'s phase-modulation function has a π/2 difference from B̅₁̅(t)'s phase-modulation function. B̅₂̅(t) applies a perpendicular magnetic field perpendicular to B̅₁̅(t)'s effective magnetic field, B_{eff}. FIG. 4 demonstrates periodic RF pulse trains, B̅₁̅(t) and B̅₂̅(t). B̅₁̅(t) is an adiabatic full passage, while B̅₂̅(t) selectively excites in the Rabi dimension. Their respective periods are τ₁ and τ₂, while their waveform periods are Δτ₁ and Δτ₂. B̅₁̅(t) and B̅₂̅(t) are interleaved to create a continuous waveform, as shown in FIG. 5. FIG. 5 shows how an interleaved selective pulse selectively excites spins in the Rabi dimension during an adiabatic full passage. The B̅₁̅(t) pulse inverts the spins, while the B̅₂̅(t) excites the spins selectively along a B₁(r) gradient, where r denotes space.

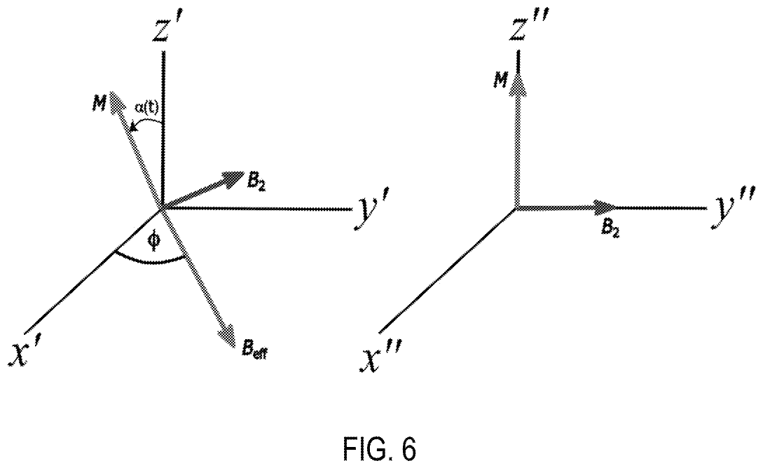

In a first frame of reference rotating at the Larmor frequency, the magnetization inverts during the adiabatic full passage. B̅₂̅(t) selectively excites spins within a bandwidth of Rabi frequencies during the inversion. In a second frame of reference rotating at B̅₁̅(t)'s B_{eff} field such that the magnetization in is the positive z″, the mechanism of B̅₂̅(t)'s selective excitation is conceptually equivalent to a standard excitation pulse, as shown in FIG. 6. The Fourier transformation of B̅₂̅(t)'s amplitude-modulation function defines the slice profile. The placement of the slice can be shifted by delivering B̅₂̅(t) with an offset transmit frequency equal to the center frequency of interest.

FIG. 6 shows the inversion of a spin during an interleaved Biselective pulse in the first rotating frame. An adiabatic full passage in its phase-modulated form creates a B_{eff} field that inverts the spins. α(t) defines the angular velocity of inversion. In a second rotating frame rotating at α(t), the B₂ pulse applies a field perpendicular to the spins in the +y″ axis. In the second rotating frame, the mechanism of selective excitation is equivalent to conventional slice-selective pulses in the first rotating frame.

The periodic nature of B̅ₙ̅(t) pulses produce an infinite number of side-bands. The slice and inversion profile repeat in the Rabi and Larmor dimension, respectively.

$${f}_{s}^{n} = {τ}_{n}^{- 1}$$

defines the spacing between the bands, while

$${f}_{h}^{n} = \frac{{f}_{s}^{n}}{2}$$

defines the highest frequency in the main-band, assuming no transmit offset

If the

$${f}_{s}^{n}$$

of both periodic pulses are equal, the transmit frequency correctly translates the slice in the Rabi dimension to the appropriate center frequency. If they are not equal, such as the case of τ₁>τ₂, higher frequencies appear as lower frequencies (e.g., aliasing). Aliasing provides a unique advantage by enabling the thinning of a slice without changing either pulse. The slice thickness can be reduced or enlarged by interleaving the B̅₂̅(t) in all or some of B̅₁̅(t). To appropriately define the slice thickness in the case of τ₁≠τ₂, α can be defined as α=τ₂/τ₁.

The slice thickness is defined as Δf₁=α·Δf where Δf defines the full-width half max of the Fourier transformation of the B₂(t) pulse. The slice's center frequency is defined as

$${f}_{1} = \frac{f}{{α}^{′}}$$

where f is the transmit offset frequency of the B₂(t) pulse.

The magnetization profile following an interleaved RF pulse is the juxtaposition of the Larmor inversion and Rabi excitation. Imperfections in the Larmor inversion profile and the linear subadiabatic region bleed into the Rabi slice profile. To isolate the Rabi excitation profile, a simple two-step phase cycling approach was developed, as shown in Table 1. Following phase-cycling, the interleaved RF pulses are able to selectively excite a slice with minimal leakage from the adiabatic full passage. The leakage that remains is the intersection of the linear subadiabtic region of the B̅₁̅(t) pulse and the Rabi slice profile of the B̅₂̅(t) pulse.

TABLE 1

| | First Rotating Frame | | Second Rotating Frame |
|---|---|---|---|
| Experiment | B₁(t) | B₂(t) | B₂(t) |
| 1 | φ(t) | φ(t) + π/2 | +x″ |
| 2 | φ(t) | φ(t) − π/2 | −x″ |

Table 1 shows how subtracting experiment 2 from experiment 1 isolates the Rabi excitation. The first multi-column demonstrates the phase cycling in the first rotating frame, while the second column demonstrates the phase cycling in the second rotating frame. In the second rotating frame, it is intuitive to understand how the subtraction between experiments sums the wanted Rabi excitation and cancels the Larmor inversion profile.

An assumption that can be made in segmenting the pulses is that the net effect on the spins is unaffected by pulse segmentation. The hard pulse approximation states that if a pulse is represented in sufficient segments, the net sum of their rotations are both linear and equivalent to the continuous case. To avoid nonlinearities, B̅₁̅(t) and B̅₂̅(t) pulses can be represented in sufficient segments. For RF pulses, waveform generators can produce complex waveforms at a high fidelity. Nothing is then lost, from the experimenter's point-of-view, to over represent the pulse waveform in thousands of segments. Thus, in some implementations, a minimum threshold can be defined as:

$${N}_{seg} \geq {N}_{Nyq} = {BW}_{Ω} \cdot {T}_{p} = R$$

where N_{seg} is the total number of pulse segments, and N_{Nyq} is the minimum number of samples required to avoid aliasing.

The B̅₂̅(t) pulse selectively excites a bandwidth of Rabi frequencies about f₁. To properly excite the slice, the spatial position of the Rabi frequencies preferably remains largely constant during the slice excitation. The ω_{eff}(t, r) function, where r and t define space and time, determines the spins frequency during B̅₂̅(t)'s application. ω_{eff}(t, r) is defined as:

$${ω}_{eff} ( t , r ) = {ω}_{1} ( t , r ) \hat{x} + Δ ω ( t ) \hat{z}$$

where ω₁(t,r) and Δω(t) define the amplitude- and frequency-modulation functions. A spatially-varying RF field transmits the adiabatic full passage. Hyperbolic secants, a widely used adiabatic pulse, are routinely used for adiabatic inversions. Their generalized amplitude- and phase-modulation functions are:

$${ω}_{1} ( t ) = {ω}_{c} + {\int }_{0}^{t} {Asech}^{2} ( {β ( \frac{2 ν}{{T}_{p}} - 1 )}^{n} ) d ν$$

$$and$$

$$ϕ ( t ) = {\int }_{0}^{t} ( {ω}_{1} ( ν ) - {ω}_{c} ) d ν$$

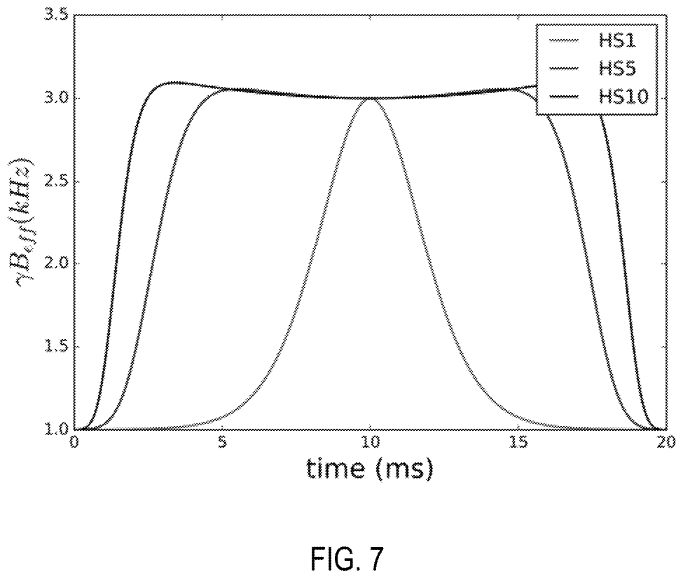

Higher-order HS pulses, as shown in FIG. 7, hold the spins' spatial frequency constant for the majority of the pulse. A B̅₂̅(t) can thus spatially select a slice of spins, while leaving spins outside the slice unperturbed. To further minimize a poor slice-selection profile caused by changing spatial frequencies, higher order HS pulses can be utilized and B̅₂̅(t) can be inserted during the middle regions of B̅₁̅(t) where the Rabi frequencies are largely constant across space.

FIG. 7 shows the ω_{eff} function of different order HS pulses. All HS pulse had an R=10 ms·1 kHz with a peak ω₁^{max}=3 kHz. The Rabi frequency holds steady at its peak frequency for higher order HS pulses, while it varies wildly for an HS1 pulse. Inserting a B̅₂̅(t) pulse during the regions where the peak γB₁(t) remains constant enables an accurate slice to be created in the Rabi dimension.

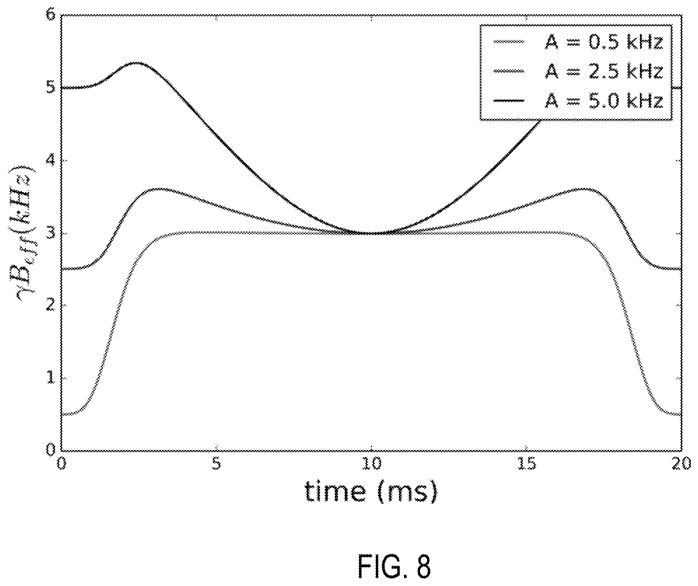

The pulse's A=BW_{Ω}/2 determines the peak effective frequency for a spin's ω_{eff} function. In the case of A<ω₁^{max}, the spins stabilize quickly to the positional Rabi frequency set by the RF field gradient ω₁^{max} value. In the case of A>>ω₁^{max}, the spins much first reach A and settle to the spatial Rabi frequency set by the RF gradient. This period, defined as the “settling time”, depends on the relationship between A and ω₁. If an A value is chosen that is too high, the majority of the pulse will see the spins' spatial Rabi frequency changing, regardless if the pulse is a higher-order HS pulse. A high A value will subsequently affect the slice and cause spins outside the bandwidth of interest to excite. To prevent this, the B̅₂̅(t) pulse can be inserted during the regions of the pulse where sufficient time has passed so that all spins nutate at the frequency of the local ω₁^{max}. A second solution is to select a pulse with a lower A value. Little is gained through high A-valued pulses since the inversion profile is phase cycled away. If a low A value is chosen, the ripples introduced by the linear subadiabatic region can be carefully placed outside the region of interest, as shown in FIG. 8.

FIG. 8 shows the ω_{eff} function for different values of A for an HS8 pulse. All pulses had R=10 with ω₁^{max}=3 kHz. The A value was varied to demonstrate variable settling times. In each case, the spins nutation begin at A, then increases slightly and eventually settles at the local ω₁^{max}=value of 3 kHz. In cases where A>>ω₁^{max} (r), the settling time can extend to the vast majority of the pulse. Lower A-valued pulses minimize excitation outside the Rabi frequencies of interest.

In some implementations, existing slice-selective AM pulses can be modified to produce B̅₂̅(t). First, a pulse waveform is chosen from traditional AM waveform, such as sinc, Gaussian, Sinnar-Le Roux, and so forth. Next, the pulse is transmitted with a transmit offset frequency, f₁, present in the amplitude modulation function of the pulse. A π/2 phase shift is added to the existing phase-modulation function of the B̅₁̅(t) pulse. The phase modulation function ensures that B̅₂̅(t) remains perpendicular to B_{eff} and selectively excites spins in the Rabi dimension. This simple protocol enables any traditional excitation pulse to selectively excite in the Rabi dimension.

Conventional Larmor selective pulses, like a sinc pulse, typically achieve a 90 degree flip angle at the middle of the pulse. The pulse is equivalent to an instantaneous 90-degree rotation at the center of the pulse. The spins accrue a B₀-dependent-phase for the remainder of the pulse. Slice-selective pulses need a refocusing lobe to remove the accrued phase. A B₀ gradient with an opposite polarity and half the length typically refocuses the spins.

Rabi selective pulses can face the same issue. The segmented B̅₁̅(t) pulse carries the analogous function as the B₀ gradient in a Larmor selective pulse. B̅₂̅(t) pulses that are not self-refocusing will accrue phase during the second half of the pulse. Assuming the hard-pulse approximation has been met, the phase that is accrued from the RF gradient is equivalent to the phase accrued by a non-segmented pulse. The phase can be defined as:

$$ψ ( r ) = \pm \frac{{T}_{p}}{2} {\int }_{- 1}^{1} {ω}_{eff} ( τ , r ) d τ$$

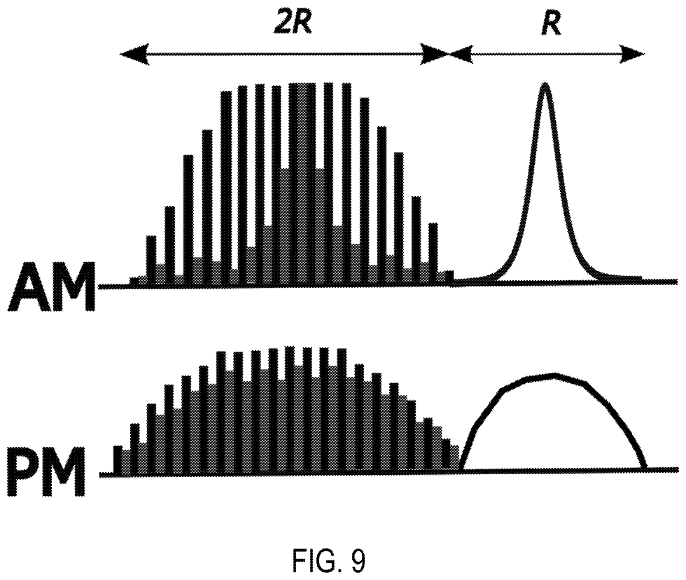

ω_{eff}(t) is a symmetric function; thus, the phase during the second half of the pulse is ψ(r)/2. To remove the phase, a refocusing B₁(t) can be applied that unwinds a phase equal to ψ(r)/2. This equation shows that a pulse half the length of B̅₁̅(t) would refocus the spins. FIG. 9 demonstrates a pulse sequence that refocuses the spins.

FIG. 9 shows a pulse sequence that selectively excites and refocuses spins in the Rabi dimension. 2R defines the time-bandwidth product of the adiabatic full passage in the interleaved B₁ selective pulse. At the end of the pulse, a slice is excited with a residual B₁(r) dependent phase, where r is space. An adiabatic pulse with a time-bandwidth equal to R refocuses the spins at the end of the pulse while retaining the slice profile.

The slice center frequency is determined by f₁ and Ω·2π⁻¹, where Ω·2π⁻¹ represents resonance offset. At a constant f₁ and changing Ω·2π⁻¹, the slice's center frequency becomes

$${f}_{eff} = \sqrt{{f}_{1}^{2} + {( Ω \cdot 2 {π}^{- 1} )}^{2}} ,$$

which is equivalent to the equation of a circle r=\sqrt{x²+y²}.

Thus, if the pulses are transmitted with a constant f₁ across a changing magnetic field, the slice will shift in accordance with the equation of a circle, and circular bands appear across the Larmor dimension. To retain a constant center frequency at f₁ across inhomogeneity, the resonance offset should be known and the transmit frequency of B̅₂̅(t) can be set equal to

$${f}_{1}^{adj} = \sqrt{{f}_{1}^{2} + {( Ω \cdot 2 {π}^{- 1} α )}^{2}} .$$

As previously described, a B₁-selective adiabatic pulse, AM_{HS1} has been introduced to perform slice and slab selection using only the B₁ gradient of a single RF coil having arbitrary geometry. The pulse produces a sharply demarcated inversion profile and is relatively insensitive to B₀ and B₁ inhomogeneities. These pulses contribute to the repertoire of sequences, especially those used for low-cost/compact MRI scanners with B₁ instead of B₀ gradients. Thus, these spatially-selective pulses provide a foundation for a palate of imaging methods and contrasts for lower cost, compact MRI systems, without sacrificing image quality. Moreover, the described pulse design opens new possibilities for creating novel tissue contrasts based on Rabi frequencies in high-rank rotating frames.

### EXAMPLES

The non-limiting examples provide simulation and experiments performed to evaluate the performance of AM_{HS1} pulse for B₁-only slice-selection and to elucidate its sensitivity to B₁ inhomogeneity and to resonance offset relative to the Larmor frequency, which occurs due to B₀ inhomogeneity. The examples also provide an implementation of a correction method that produces a uniform arbitrary flip angle across the slice or slab when using a single, inhomogeneous B₁ coil. The examples also demonstrate the presence of rotary echoes when AM_{HS1} is applied as a double spin echo in simulation.

### Example 1

The following examples show that a B₁-selective adiabatic pulse, referred to as AM_{HS1}, can successfully perform slice-selection using only 1-gradients. As will be shown, the pulse is relatively insensitive to B₁ inhomogeneity and is still somewhat sensitive to B₀ inhomogeneity at low B₁ values, maintaining a clean slice profile for inversion pulses. This pulse sequence adds a valuable tool to the repertoire of pulse sequences, especially those used for low-cost/compact MRI systems that utilize B₁ instead of B₀ gradients.

### Methods

A Bloch simulator based on a 4^{th}-order Runge-Kutta solver was written in Python in the first rotating frame. Resilience to B₀ inhomogeneity was investigated by varying the Larmor frequency offset Ω. For all other simulations, unless noted otherwise, Ω=0, T₁=T₂=100 s (to effectively ignore relaxation), time step dt=1e−6 s, and

$${ω}_{1 y}^{′} / 2 π$$

varied from 0-10000 Hz. Visualizations were written using custom Python and MATLAB scripts. Initial magnetization M₀ is specified as a vector indicating the starting position of the magnetization along x′, y′, and z′ (formatted [x′ y′ z′] with origin [0 0 0]).
Slice Selection with Two Coils

A band of Rabi frequencies can be selectively inverted when

$${B}_{1 x}^{′}$$

is an adiabatic HS1 pulse applied with a

$${B}_{1 y}^{′}$$

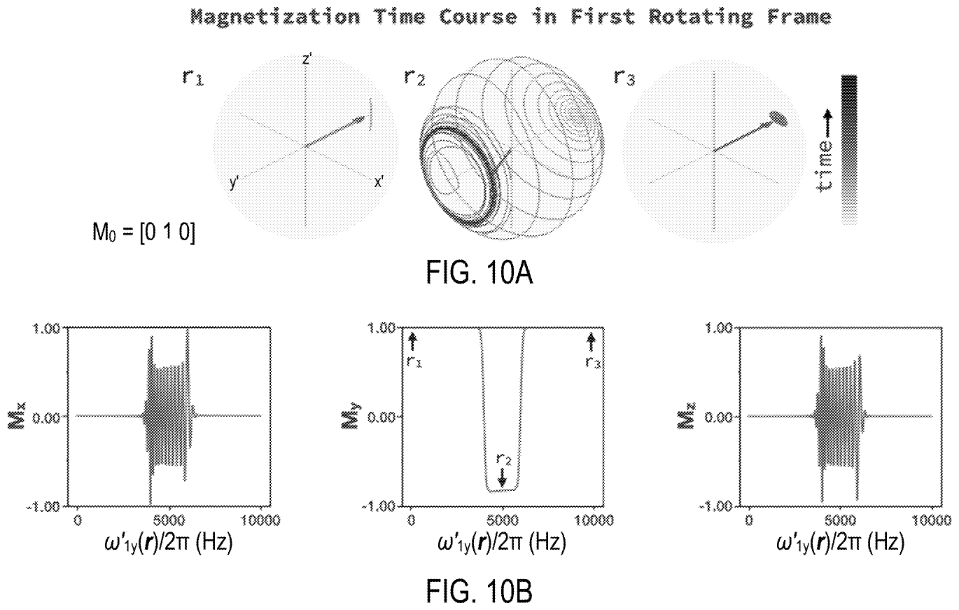

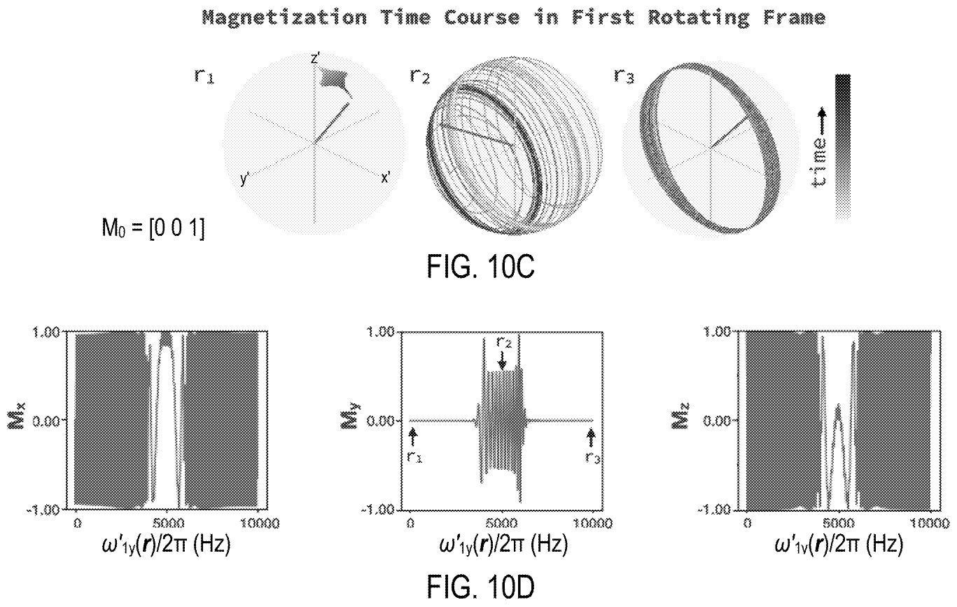

gradient that generates a continuum of Rabi frequencies in the x′z′ plane. This simulation assumes two RF coils orthogonal to each other along the x- and y-axes in the lab frame. Results are shown in FIGS. 10A-10D. The pulse parameters were chosen just below the threshold for full adiabaticity. Simulations for slice selection using AM_{HS1} on two coils, as shown in FIGS. 10A-10D used the following settings: center Rabi frequency

$${ω}_{1 y}^{′} ( {r}_{c e nter} ) / 2 π = 5000 Hz , {ω}_{1 x}^{max} / 2 π = 1000 Hz , {T}_{p} = 10 ms ,$$

R=20 (pulse bandwidth=2000 Hz), and M₀=[0 1 0] or [0 0 1].

### Extending Slice Selection to One Coil

Use of a single coil can facilitate the implementation of B₁-selective methods and allow for their extension to parallel transmit arrays. Specifically, parallel transmission enables the synthesis of relatively linear RF gradients by allowing tailored weightings of the individual coil amplitudes. Regardless of whether the RF coil is a simple surface coil or a parallel transmit array, AM_{HS1} is synthesized from the

$${B}_{1 x}^{′} and {B}_{1 y}^{′}$$

components of the two-coil case, but implemented as real and imaginary components of the (single) pulse.

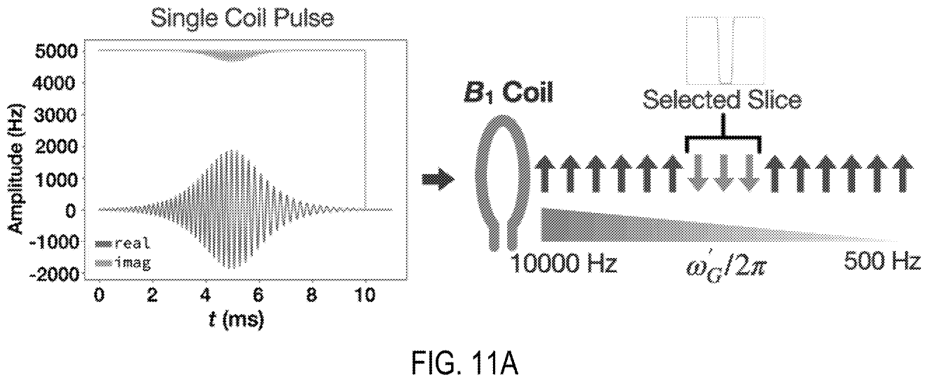

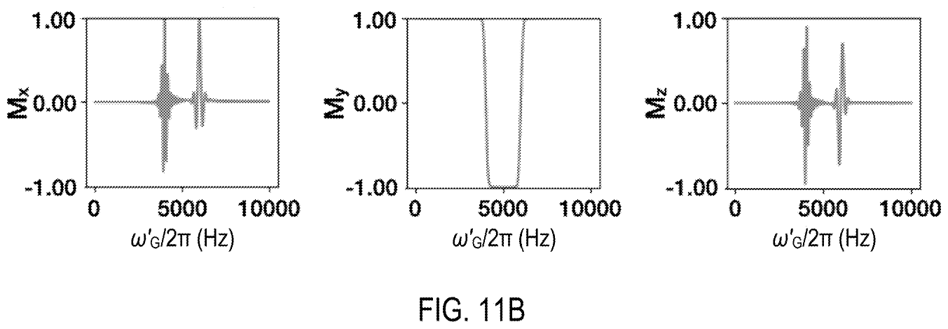

As shown in FIGS. 11A-11B, simulations of slice inversion with a single coil used an AM_{HS1} pulse with

$${ω}_{1 y}^{′} ( {r}_{c e nter} ) / 2 π = 5000 Hz$$

(again

$${ω}_{1 y}^{′} / 2 π$$

is varied from 0 to 10000 Hz),

$${ω}_{1 x}^{max} / 2 π = 2000 Hz ,$$

Tₚ=10 ms, R=20, and M₀=[0 1 0].

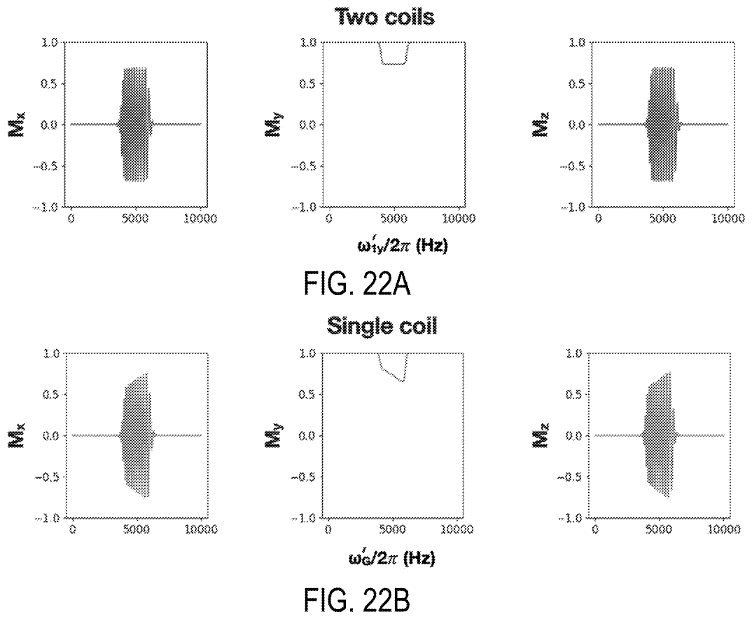

Simulations demonstrating sub-adiabatic excitation (θ≤90°) using AM_{HS1} with one coil versus two coils were also performed (FIGS. 22A-22B). The simulation parameters were: Tₚ=10 ms, AM_{HS1} pulse with

$${ω}_{1 y}^{′} ( {r}_{c e nter} ) / 2 π = 5000 Hz , {ω}_{1 x}^{max} / 2 π = 250 Hz ,$$

Tₚ=10 ms, R=20, and M₀=[0 1 0].

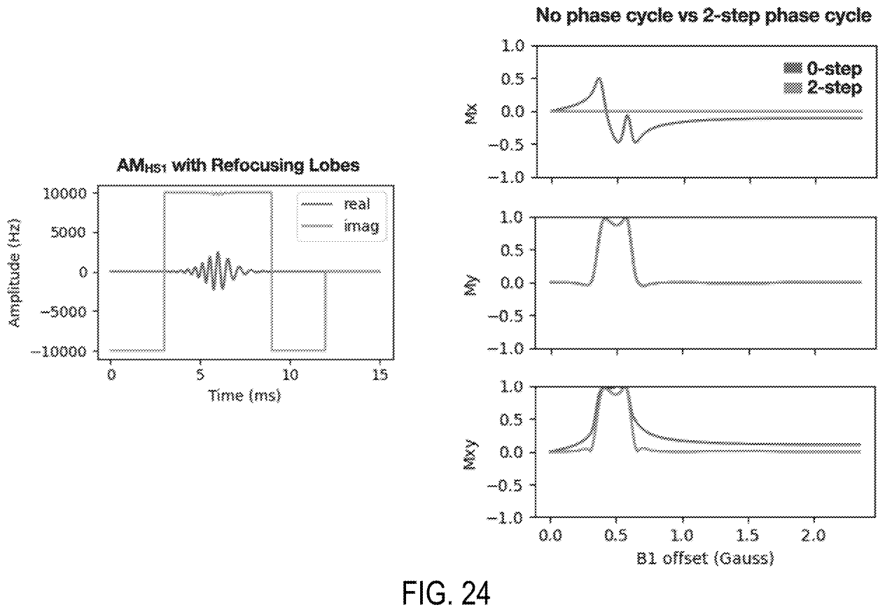

To remove the linear and quadratic phase produced by starting with M₀=[0 0 1] with a single coil, a version of AM_{HS1} with B_{1y} refocusing lobes was also investigated, as shown in FIG. 24. The total refocusing lobe length was the same as the original

$${B}_{1 y}^{′}$$

gradient length and was appended to the beginning and end of the AM_{HS1} pulse. A two-step phase cycle was performed by running the simulation again with negative phases and averaging the magnetization profiles of the two simulations. Subsequently the amplitude-correction procedure described above was implemented where the original shape function F₁(t) was scaled by the normalized frequency sweep and phase modulation functions, as described above, for both phase cycle steps. Simulation parameters were:

$${ω}_{1 y}^{′} ( {r}_{c e nter} ) / 2 π = 1000 Hz , {ω}_{1 x}^{max} / 2 π = 200 Hz ,$$

Tₚ=11.98 ms (including refocusing lobes), R=10.4, M₀=[0 0 1], and an applied gradient

$${ω}_{G}^{′} / 2 π = 0 - 5000 Hz .$$

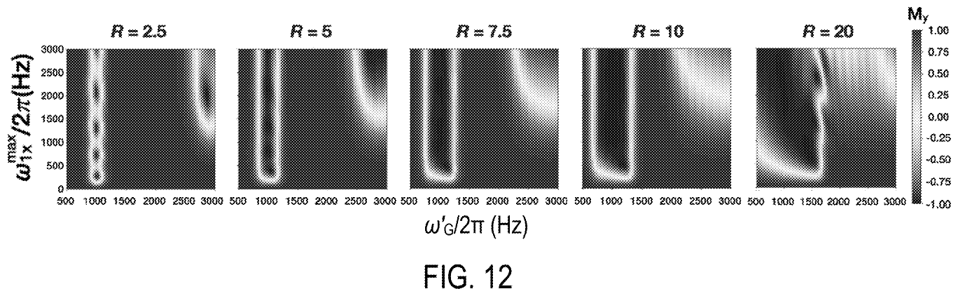

As shown in FIG. 12, simulations were also performed to examine the slice profile for one coil when restricting the maximum RF amplitude, as in clinical MRI. These simulations assumed a B₁ gradient of

$${ω}_{1 y}^{′} ( r ) / 2 π ) = 500 - 3000 Hz ( 1000 steps ) and {ω}_{1 y}^{′} ( {r}_{center} ) / 2 π = 1000 Hz .$$

The amplitude of the frequency-swept component,

$${ω}_{1 x}^{max} / 2 π ,$$

was varied from 0 to 3000 Hz. Increasing R values (2.5, 5, 7.5, 10, and 20) were evaluated. Other parameters were: Tₚ=15 ms and M₀=[0 1 0].

By operating below the threshold for adiabaticity, it is possible to produce flip angles <180°, although the sensitivity to B₁ inhomogeneity returns, as with conventional sub-adiabatic HS1 pulses in the first rotating frame. When transmitting AM_{HS1} with a single coil under sub-adiabatic conditions, the flip angle in slice will vary in proportion to

$${B}_{1 x}^{′} ( r ) .$$

Furthermore, when starting from M₀=[0 0 1], oscillations with frequency proportional to

$${ω}_{1 y}^{′} ( r )$$

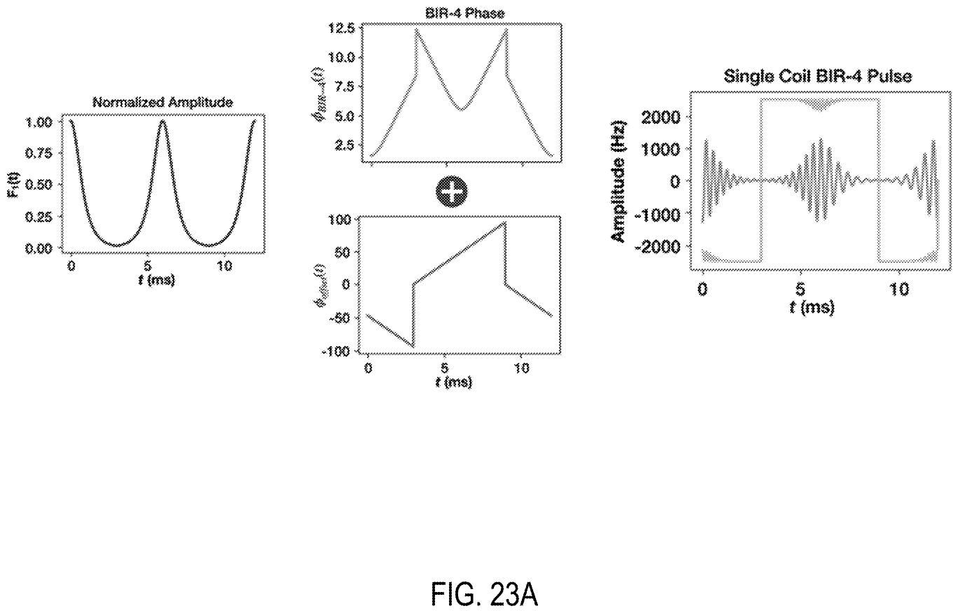

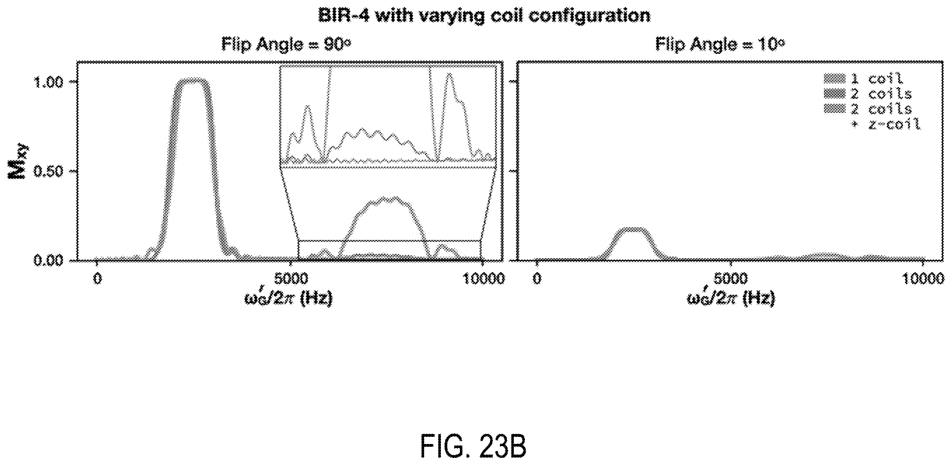

appear outside of the selected slice. Here, a method is represented to flatten this profile using BIR-4. Simulations were performed to analyze its effectiveness, as shown in FIGS. 23A-23B.

For this conversion to BIR-4, the amplitude and phase functions for AM_{HS1} can be split and reflected on either end of a single AM_{HS1} pulse as previously shown. Phase shifts are then applied before and after the middle pulse to determine the flip angle:

$${Δϕ}_{BIR - 4} = π + \frac{θ}{2}$$

Phases at the points of highest

$${B}_{1 x}^{′} ( t = 0 , {T}_{p} , and 2 {T}_{p} )$$

can be carefully set such that they are close to either

$$\pm \frac{π}{2} ( without phase shifts )$$

to ensure a flat magnetization profile. This ensures maximum B′₁ₓ at the center of the slice to produce a frequency sweep that is symmetric. The phase ramps used to center the slice can then be split and reflected in a similar manner. These additional reflected segments must also be flipped in sign.

Simulation parameters for BIR-4 were:

$${ω}_{1 y}^{′} ( {r}_{center} ) / 2 π = 2500 Hz , {ω}_{1 x}^{max} / 2 π = 1500 Hz ,$$

Tₚ=11.98 ms (including the refocusing lobes), R=5.75, θ=90° and 10°, M₀=[0 0 1] and dt=1e−7 s. These simulations were performed for a single coil, two coils, and two coils plus a z-coil that assumes the same field as

$${B}_{1 x}^{′}$$

although 90° out of phase to produce a circularly polarized x′z′ field.

### Off Resonance and B₁ Inhomogeneity Performance

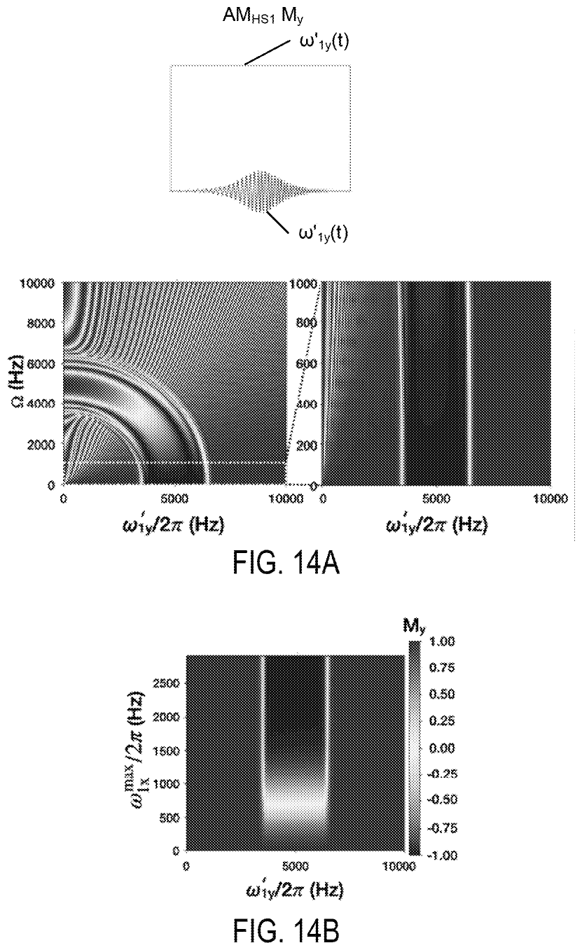

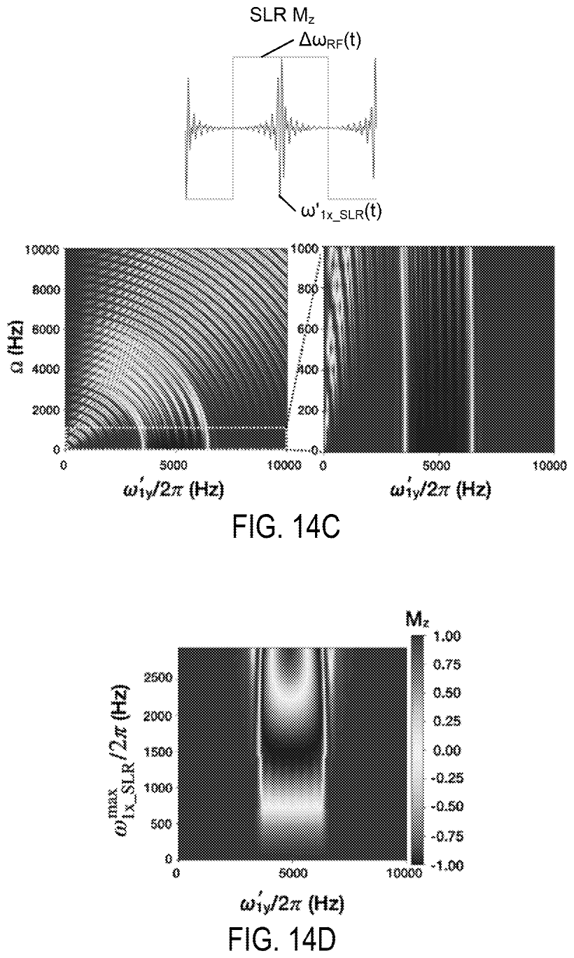

Adiabatic inversion with AM_{HS1} under increasing off resonance Ω was compared with a Shinnar-Le-Roux (SLR) optimized B₁-selective pulse, as shown in FIGS. 14A-14D. For the AM_{HS1} pulse the following parameters were used: two coils,

$${ω}_{1 y}^{′} ( {r}_{center} ) / 2 π = 5000 Hz , {ω}_{1 x}^{max} / 2 π = 3000 Hz ,$$

Tₚ=10 ms, R=30, and M₀=[0 1 0].

For the SLR pulse the version using a split and reflected construction for the pulse was used since θ>90°. Simulation parameters were: two coils,

$${ω}_{1 y}^{′} ( {r}_{center} ) / 2 π = 5000 Hz ,$$

Tₚ=10 ms (two 5 ms segments), flip angle θ=180°, R=15, M₀=[0 0 1]. The x′-axis RF component

$${ω}_{1 x}^{′} / 2 π$$

was stepped from 0-10000 Hz.

Next these two pulses were compared under increasing

$${B}_{1 x}^{′}$$

magnitude to demonstrate performance under inhomogeneous B₁ and adiabaticity, as shown in FIGS. 14B and 14D. The same settings were used for these simulations as above,
Rotary Echoes with AM_{HS1}

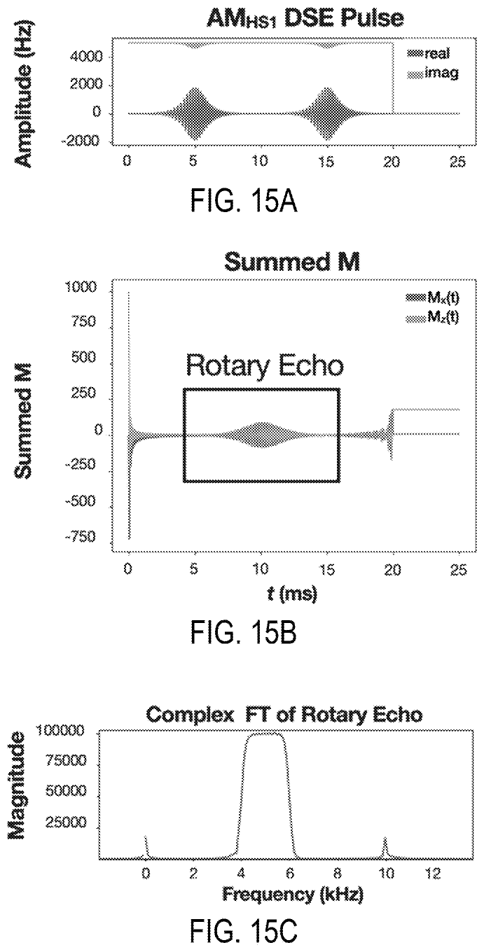

AM_{HS1} was initially prepared to experimentally demonstrate its utility in a double spin-echo sequence; however, during this process a rotary echo was found along the x′z′ plane and investigated, as shown in FIGS. 15A-15C. For this simulation, the following parameters were used: one coil,

$${ω}_{1 y}^{′} ( {r}_{center} ) / 2 π = 5000 Hz , {ω}_{1 x}^{max} / 2 π = 2000 Hz ,$$

Tₚ=10 ms, R=20, cutoff=0.001 (to reduce Gibbs ringing), and M₀=[0 0 1]. A complex FT was taken over t=5-15 ms during the pulse.

### Experimental Demonstration of AM_{HS1}

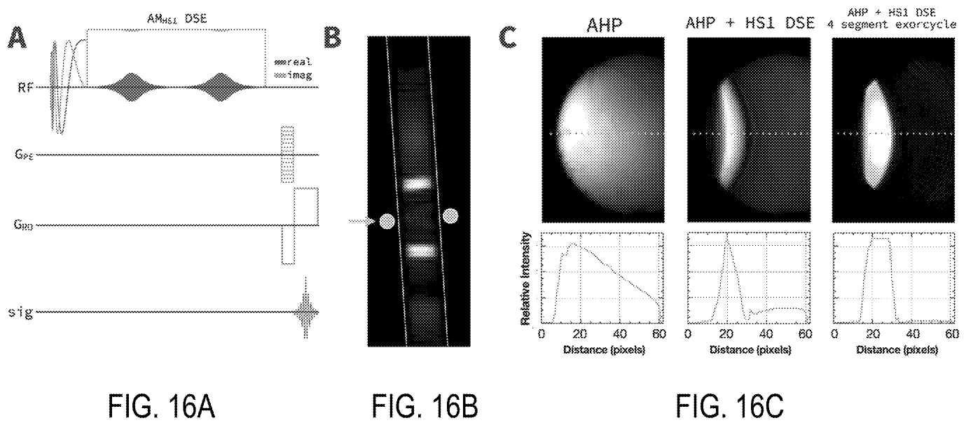

Experimental data were acquired on a 9.4 T Bruker MRI System on phantoms containing deionized (DI) water with 50 mM NaCl and 1% CuSO₄, as shown in FIGS. 16A-16C. Surface coils having 1.5-cm and 3-cm diameters were used to image a 0.6-cm diameter tube and a 3.8-cm diameter sphere, respectively. The tube was placed symmetrically through the plane of the coil. The full B₁-selective pulse sequence consisted of a 4-ms adiabatic half passage (AHP) followed by two consecutive 5-ms AM_{HS1} pulses to form a double spin echo (DSE). Frequency- and phase-encoding with B₀ gradients were performed only to visualize the slice profile. The pulse settings were

$${ω}_{1 x}^{max} / 2 π = 2000 Hz ( sphere ) , 1000 Hz ( tube ) ; {ω}_{1 y}^{′} ( {r}_{center} ) / 2 π = 5000 Hz ( sphere ) , 2000 Hz ( tube ) ,$$

the largest value of

$${ω}_{G}^{′} / 2 π = 10000 Hz ,$$

T_{R}=100 ms, T_{E}=6.828 ms (from DSE center), RF power=9.9 W (tube), 54.8 W (sphere). To remove out-of-band coherences, a 4-segment EXORCYCLE was performed on the 2^{nd} AM_{HS1} pulse.

### Results

As shown in FIGS. 10A-10D, a band of spins can be selectively altered in space, when

$${B}_{1 x}^{′}$$

is as an adiabatic HS1 applied in concert with a

$${B}_{1 y}^{′}$$

gradient that generates different spin nutation frequencies in the x′z′ plane. FIGS. 10A and 10B demonstrate slice selection using AM_{HS1} pulse along a

$${B}_{1 y}^{′}$$

with initial magnetization M₀=[0 1 0]. FIG. 10A shows a magnetization vector time course in the first rotating frame for three positions along the B_{1y} gradient, r₁ and r₃ being far off resonance, and r₂ being at the center of the slice on-resonance. FIG. 10B shows magnetization components Mₓ, M_{y}, and M_{z} sampled along the

$${B}_{1 y}^{′}$$

gradient at the end of the pulse, demonstrating nearly complete inversion of spins from +y′ to −y′. The results are straightforward for spins initially oriented along the y-axis, demonstrating a distinct slice of spins that is inverted for the specified bandwidth with a spread of phases along the x′z′ plane. This remains true for spins oriented along the z′-axis, but the spatial location is less clean, as shown in FIGS. 10A-10D. A slice is observed at the expected location though it is spread across the x′z′ plane. FIGS. 10C and 10D demonstrate slice selection using AM_{HS1} pulse with initial magnetization M₀=[0 0 1]. FIG. 10C shows a magnetization vector time course in the first rotating frame for three positions along the B_{1y} gradient, r₁ and r₃ being far off resonance, and r₂ being at the center of the slice on-resonance. FIG. 10D shows magnetization components Mₓ, M_{y}, and M_{z} sampled along the B_{1y} gradient at the end of the pulse demonstrating movement primarily towards −x′.

As FIGS. 10A-10D demonstrate, simulations for B₁-based slice selection using AM_{HS1} with two coils show distinct slices at the expected locations starting with M₀ oriented along the y′ and z′-axes for each simulation, respectively. For M₀ oriented along the z′-axis a series of oscillations are superimposed over the slice. These oscillations may be cancelled by phase cycling.

For M₀ oriented along the z′-axis a series of oscillations are superimposed over the slice. While undesirable, these oscillations may be cancelled by phase cycling combined with refocusing lobes. As will be discussed later, this can be accomplished with two phase cycles without much distortion to the slice profile, as shown in FIG. 24. Without phase cycling, slice selection starting with an initial magnetization of M₀=[0 0 1], as is typical, can be provided using a preparatory non-selective 90° pulse prior to applying the above AM_{HS1} RF pulse. Alternatively, one could flip the direction of the AM_{HS1} RF pulse to be along the z-axis and apply the B_{1y} gradient along the x′-axis. In this case, frequency modulation can be used to modulate the off-resonance field as opposed to the current scheme of pure amplitude modulation. Overall, this set of simulations demonstrates the feasibility of using adiabatic pulses for slice inversion, with best performance being shown for M₀=[0 1 0].

While slice selection is possible with two coils, as shown in FIGS. 10A-10D, implementation in pulse sequences can be simplified when slice selection can be achieved with a single coil and, therefore, a single transmit channel. Moreover, the ability to use a single coil for producing the B₁ gradient (ω₁ₓ) and the Rabi precession (ω_{1y}) can make it easier to deploy these RF pulses in multi-channel coil (e.g., parallel transmit) applications. Single-channel implementation is readily accomplished by treating the x and y components of the B₁ field for each of the two coils as the real and imaginary components of a single coil as previously discussed.

Making the net amplitude across B₁ₓ and B_{1y} constant in time produces a slight variation in the amplitudes of B_{1y}, but still produces reasonable inversion for the selected slice when starting with M₀=[0 1 0]. FIGS. 11A-11B demonstrate slice selection using a single coil to produce an AM_{HS1} pulse. FIG. 11A shows real and imaginary components of an AM_{HS1} pulse generated by a single coil. The amplitude modulation of the real component produces a frequency sweep that inverts spins within its bandwidth. FIG. 11B shows magnetization components Mₓ, M_{y}, and M_{z} sampled along the B₁ gradient at the end of the pulse demonstrating inversion from +y′ to −y′.

As FIGS. 11A-11B demonstrated, slice inversion was accomplished well when moving from two-coils to one coil. However using a single coil, the pulse profile varies with position if the pulse is not applied with sufficient power. The maximum B₁ₓ,

$${ω}_{1 x}^{max} ,$$

can be increased from 1000 Hz in the two-coil case by a factor of √2 to approximately 1414 Hz in the one coil case to maintain full inversion because the excitation pulse B₁ₓ is now linearly polarized instead of circularly polarized.

While spin inversion has been shown in the illustrated examples for simulation, the ratio between the B₁ₓ and B_{1y} should be considered for practical implementations. For example, clinical scanners may not have the range of RF powers simulated here. To qualitatively determine reasonable ranges for B₁ₓ and B_{1y}, the same simulations were repeated for increased B₁ₓ using values closer to what would be expected on a clinical MRI scanner, as shown in FIG. 12. FIG. 12 demonstrates slice inversion as a function of increasing

$${ω}_{1 x}^{max} / 2 π$$

and increasing R value for an AM_{HS1} pulse that is centered at 1000 Hz and produces a gradient 500-3000 Hz, closer to the max RF power output for clinical MRI scanners.

As FIG. 12 demonstrates, maintaining a large ratio between B_{1y} and B₁ₓ may be desirable to avoid unwanted excitations. In the examples provided, it was shown that an R value of at least ~7.5 or greater can ensure the pulse to be adiabatic. In the present examples, above R=10 the pulse profile started degrading. This is likely from the interference of a separate wider slice at approximately 3 times the center frequency when high

$${ω}_{1 x}^{max}$$

values are used. This interference is most apparent at R=20 and

$${ω}_{G}^{′} / 2 π \approx 1500$$

Hz where the slice profile degrades as the two excitation bands overlap. As the R value increases at fixed pulse duration, the Rabi frequencies in the sweep extend to both lower to higher values. As the sweep includes more low frequencies, the rotating wave approximation becomes more difficult to satisfy, and as a result, the slab profile deteriorates. This was also seen in an SLR-optimized version of Bloch-Siegert imaging, and was explained as multiphoton resonances. Hoult noted that B₁-selective imaging maintains selectivity when B₂<<B₁, which corresponds to

$${B}_{1 x}^{′} ≪ {B}_{1 y}^{′} .$$

The extent of tolerable out-of-band excitations may vary. In some implementations, it is preferable to ensure

$${B}_{1 y}^{′} > 2 {B}_{1 x}^{′} .$$

While the precise mechanism for these excitations is unclear, it is contemplated that this represents a violation of the rotating wave approximation. Yet, these simulations show that AM_{HS1} is feasible when using B₁ amplitudes accessible to clinical MRI given

$${B}_{1 y}^{′} : {B}_{1 x}^{′}$$

is set properly.

Moving from two coils to one coil produces an uneven pulse profile for subadiabatic pulses that do not produce complete inversion, as illustrated in FIGS. 22A-22B. Furthermore a non-selective 90° pulse can be used to avoid the linear and quadratic phases produced when starting with M₀=[0 0 1] as is typical. One option to remove these phases is to apply a refocusing lobe to either end of the pulse in addition to a two-step phase cycle. A single shot solution is to use a B₁-Insensitive Rotation (BIR), such as a BIR-4 pulse, method.

A side effect that arises when moving to a single coil is that, for subadiabatic pulses below the

$${ω}_{1 x}^{max} / 2 π = 1414$$

Hz threshold, the pulse profile is quadratic rather than flat. In the two-coil case,

$${B}_{1 x}^{′}$$

was homogenous over the object; however in the one coil case, the real component of B₁, which corresponds to

$${B}_{1 x}^{′} ,$$

forms a linear gradient over the object. While this does not produce any issues for inversion pulses, pulses that require any flip angle lower than 180° will produce an uneven profile. To correct for this, AM_{HS1} can be reconstructed as a BIR-4 pulse. This allows for even slice profiles at low flip angles when starting with M₀ aligned with the z-axis as is typical. While the phases should be carefully set to ensure a symmetric pulse, flat pulse profiles have been observed for flip angles of 90° and 10° (FIGS. 23A-23B). An unexpected side effect of this is that a separate, wider bandwidth, lower flip angle excitation at 3 times the center frequency appears as mentioned earlier. This is possibly related to the ratio of

$${B}_{1 y}^{′} : {B}_{1 x}^{′}$$

being too high as this issue dramatically reduces with the presence of two coils where the

$${B}_{1 x}^{′}$$

component no longer is a gradient. This can also be reduced by utilizing longer pulses, however this may be undesirable due to SAR concerns. The addition of field along the z-axis, 90° out of phase with

$${B}_{1 x}^{′}$$

to produce a circularly polarized x′z′-field further reduces the out-of-band excitation. This may be included as a coil resonating in the kHz range along z. An alternative method that would not require two coils for low flip angle excitation and reasonable B₁ strengths uses the original AM_{HS1} pulse with B_{1y} refocusing lobes and a 2-step phase cycle (FIG. 24). The phases for this refocused pulse may be set similarly to BIR-4 where the phase at the center of the pulse ±90°. Regardless of the method of B₁ compensation, this could theoretically provide a method for uniform low flip angle excitation with a simple surface without the need for B₁ mapping and could be applied to quantitative mapping of T₁, flip angle, etc. This could particularly benefit parametric maps at high field where B₁ fields become more inhomogeneous and SAR is of higher concern at larger flip angles.

As shown, full adiabatic inversion can be achieved even in the presence of field inhomogeneity in the one-coil case. When executing the pulse under subadiabatic conditions, an uneven excitation profile may be produced, as shown in FIGS. 22A-22B. However, in some implementations, scaling the pulse as previously described can produce even excitation profiles.

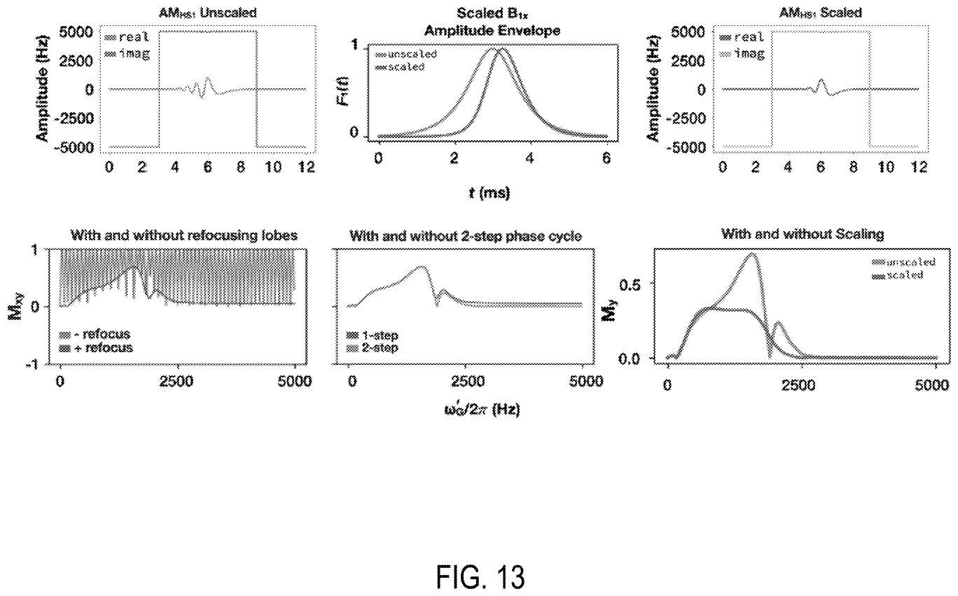

Moreover, when M₀=[0 0 1], the phase of the final magnetization may vary linearly and quadratically across space. To eliminate undesirable oscillations, refocusing lobes can be applied to both ends of the pulse with a two-step phase cycle, as shown in FIG. 13. The latter removes a dispersive component in the magnetization profile. For large R values and use of a single coil, the slice profile may still have some dependence on the

$${B}_{1 x}^{′}$$

gradient. Therefore, a second correction can be applied by scaling the shape function by a normalized version of the frequency sweep and phase-modulation functions. As shown in the example provided in FIG. 13, this slice profile correction can reduce the slice inhomogeneity from 33.5% to 4.1% over a 435 Hz bandwidth (at the height of the excitation profile).

FIGS. 14A-14D provide a comparison of the presently described method with previously described pulses. The AM_{HS1} pulse was compared with a Shinnar-Le-Roux (SLR) optimized B₁-selective pulse, which modulates a z′-axis off-resonance field in a frame rotating at ω₀+Δω_{RF}(t) to generate slice selection. The pulse shape of the z′-axis off resonance field is optimized through the SLR algorithm and a

$${B}_{1 x}^{′}$$

gradient is applied along the x′-axis. The B₁-selective SLR-pulse was recreated to excite the same specified bandwidth as our AM_{HS1} pulse. Since rotation occurs in the Larmor frame, the SLR pulse is instead formed similarly with an x and y-component rather than an x and z-component. The behavior of both pulses was compared when a constant off resonance field is added along the z′-axis to simulate B₀ inhomogeneity, as shown in FIGS. 14A and 14C. The two pulses were also compared with increasing B₁ amplitude, thus examining pulse robustness to B₁ inhomogeneity, as shown in FIGS. 14B and 14D.

Comparison of the inversion pulse profiles achieved is provided in FIGS. 14A-14D. The AM_{HS1} adiabatic B₁-selective pulse is shown in FIGS. 14A-14B, and the SLR B₁-selective pulse is shown in FIGS. 14C-14D. FIG. 14A shows off resonance performance for the AM_{HS1} pulse shown on the left, where M starts from M₀=[0 1 0]. The M_{y} amplitude along a

$${B}_{1 y}^{′}$$

gradient along the x-axis is plotted in the middle left as the off resonance increases along the y-axis. The same graph is shown but zoomed in from 0-1000 Hz off resonance in the middle right FIG. 14B shows the inversion pulse profile for AM_{HS1} as a function of

$${ω}_{1 x}^{max} ,$$

the peak B₁ₓ value, showing slice profile in the presence of B₁ inhomogeneity. Similar graphs for off resonance (FIG. 14C) and inversion profile vs B₁ inhomogeneity (FIG. 14D) are shown for the SLR B₁-selective pulse starting with M₀=[0 0 1].

As FIGS. 14A-14D demonstrate, although both pulses degrade with off resonance, something interesting happens with AM_{HS1}: the slice rotates towards the off-resonance field axis while maintaining inversion. The SLR pulse curves towards the off-resonance axis similarly, however this reduces in inversion magnitude. Thus, in some implementations, curved slice excitations can be produced by applying a B₀ gradient along the y′-axis and a B₁ gradient along the x′-axis, as shown.

Both pulses were examined over a range of 0-1000 Hz. Both demonstrate a straight profile with increasing off-resonance field as shown, but the SLR pulse demonstrates more ripples in the slice profile with higher off resonance.

As is expected, the AM_{HS1} behaves adiabatically, in that above a threshold B₁ₓ amplitude, the pulse profile remains the same. Thus, AM_{HS1} maintains an even slice profile if the B₁ₓ amplitude is greater than this threshold. The SLR pulse, which closely resembles a sinc pulse that is formatted similarly to BIR-4, is not adiabatic and therefore does not maintain inversion with increasing B₁ amplitude.

For more practical slice selection, AM_{HS1} can be implemented as a double spin echo (DSE), however a side effect of this is that a full rotary echo can be seen during the pulse along the xz-plane, as shown in FIGS. 15A-15C. One can take the Fourier transform (FT) of this rotary echo during the pulse and obtain a projection corresponding to the excited slab (in addition to two peaks a 0 Hz and twice the center frequency). FIG. 15A shows a DSE composed of two 10 ms segments. FIG. 15B shows magnetization components Mₓ(t) and M_{z}(t) showing presence of rotary echo. FIG. 15C shows a complex Fourier transform of Mₓ(t)+j*M_{z}(t) from 5 ms to 15 ms.

As shown in FIGS. 15A-15C, a full rotary echo was produced at the center of the DSE in the xz-plane. Performing a complex FT of Mₓ(t) and M_{z}(t) produces a clean slab corresponding to the band of Rabi frequencies which are excited by the pulse in addition to two peaks at 0 Hz and twice the center frequency of the pulse. This remains true using only Mₓ(t) or M_{z}(t) for the FT. FIGS. 15A-15C also show that a cutoff of 0.001 on the HS1 pulse waveform can be used to form a clean slice, reducing Gibbs ringing over the slice. In some implementations, this rotary echo can be used for simultaneous transmit and receive (STAR) by either sensing along the z-axis with a sensor tuned to the relevant Rabi frequency or performing a gapped pulse sequence such as SWept Imaging with Fourier Transform (SWIFT). This could be particularly useful for a radially acquired STAR or SWIFT sequence, allowing rapid averaging during each spoke of the acquisition.

Slice selection using AM_{HS1} in a DSE format is demonstrated experimentally on a tube and a spherical water phantom at 9.4 T using only surface coils, as shown in FIGS. 16A-16C. The pulse sequence for AM_{HS1} is applied as a double spin echo, as shown in FIG. 16A. The full pulse sequence involves a 4 ms adiabatic half passage (AHP) pulse to initialize all spins along the y-axis and subsequently applying an 8 ms AM_{HS1} DSE pulse (two 4 ms segments). The phase encode (G_{PH}) and readout (G_{RO}) gradients are used purely for visualization of the slice. A B₀ readout is used purely for visualization. Slice position was adjusted by changing coil power or φ_{off}(t).

FIG. 16B shows slice selection for a surface coil placed at the center of a tube with slices on either end. Two slices are visualized in the tube because the coil profile is symmetric across the coil position. FIG. 16C shows slice selection for a surface coil placed on the left side of the sphere shown. The image is shown after the 4-ms AHP on the left; after 4-ms AHP+two consecutive AM_{HS1} in the middle; and after 4-ms AHP+two consecutive AM_{HS1} as a 4-segment EXORCYCLE on the right. Relative image intensity along dotted line is shown below each image. A curved 3D slice is excited in the sphere which is further localized using a 4-segment EXORCYCLE.

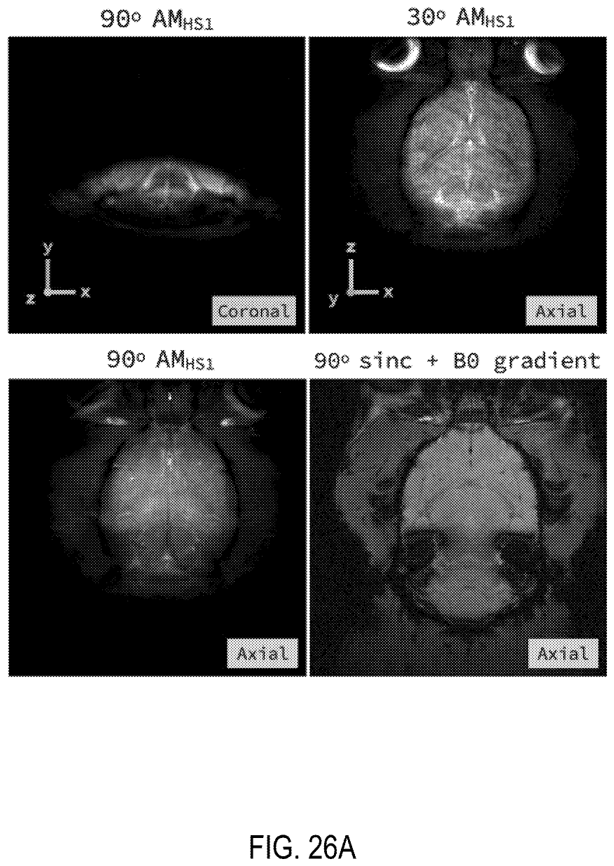

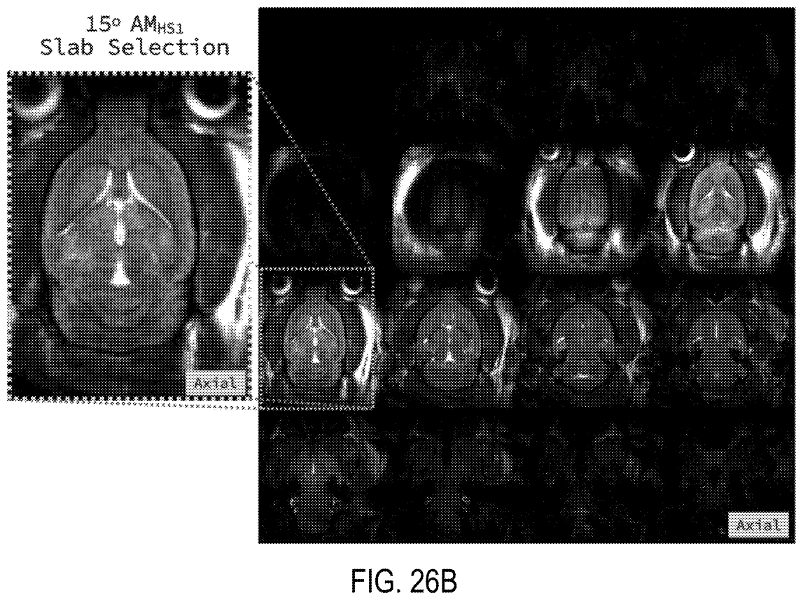

Slice and slab selection using an AM_{HS1} pulse was demonstrated experimentally in vivo to image rat brains, as shown in FIGS. 26A-26B. FIG. 26A demonstrates slice selection using 90° and 30° AM_{HS1} pulses with refocusing lobes, two-step phase cycles and averaging showing coronal and axial views of rat brain with contrast highlighting cerebrospinal fluid (CSF) and vasculature. This is compared to slice selection using a 90° sine pulse in a 2D GRE sequence. FIG. 26B shows slab selection using 15° AM_{HS1} with slice profile correction instead of B₀ gradients and larger R value. (Left) Central slice shows stronger contrast of CSF and vasculature. (Right) Montage showing slab selectivity along the B₁ gradient in the FOV.

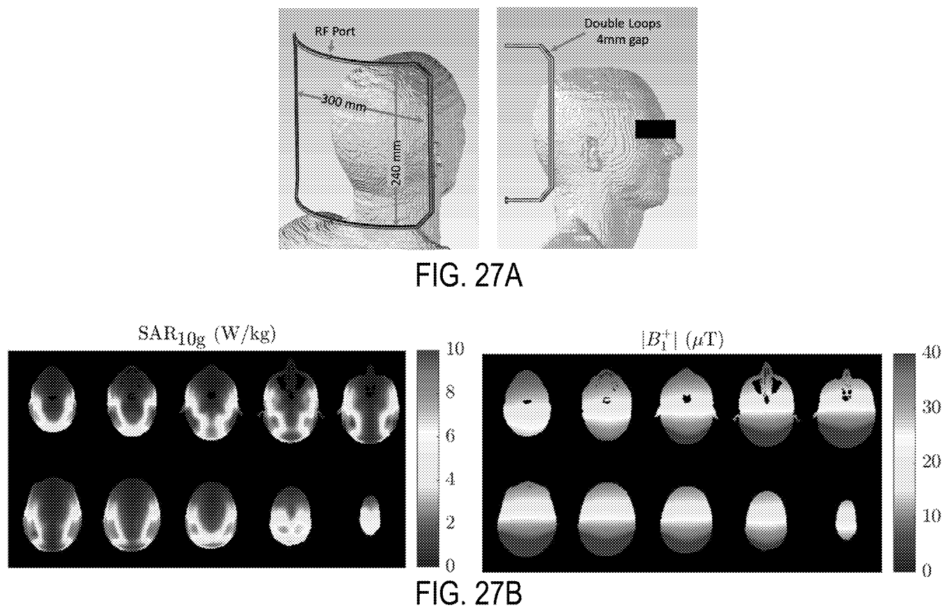

In some implementations, B₁-selective pulses may be applied clinically at low- to mid-field strengths. For example, they can be applied using a 0.7 T head-only system. Full-wave 3D EM simulations of B₁ and SAR, shown in FIGS. 27A-27B demonstrate that a single curved double-loop coil can produce the same

$$γ {B}_{1}^{+} / 2 π$$

attained at 9.4 T of 1000 Hz approximately halfway into the head at 0.7 T. This can allow for slice selection of deep brain using AM_{HS1}. Furthermore, the average and peak 10 g SAR meet FDA and IEC limitations at 0.7 T, and thus, demonstrate the ability to safely perform human scans. In some implementations, a z-coil tuned to the Rabi frequency of interest can be used to create a circularly-polarized field in the x′z′-plane, reducing unwanted excitations outside of the band of interest, which allows for lower B₁ to be used for slice selection.

### Example 2

A series of computer simulations were performed to demonstrate slice selection under a wide array of conditions. Conditions held constant across all results were the use of HS pulses, a linear γB₁(r) gradient from 1 to 10 kHz, and that the B̅₁̅(t) pulse was described with 2000 elements. The B̅₂̅(t) pulse was a truncated two-lobe Sinc pulse. Phase cycling was applied according to Table 1, and the resilience to resonance offset between 3 kHz was tested. The transmission offset was adjusted for all cases as previously described.

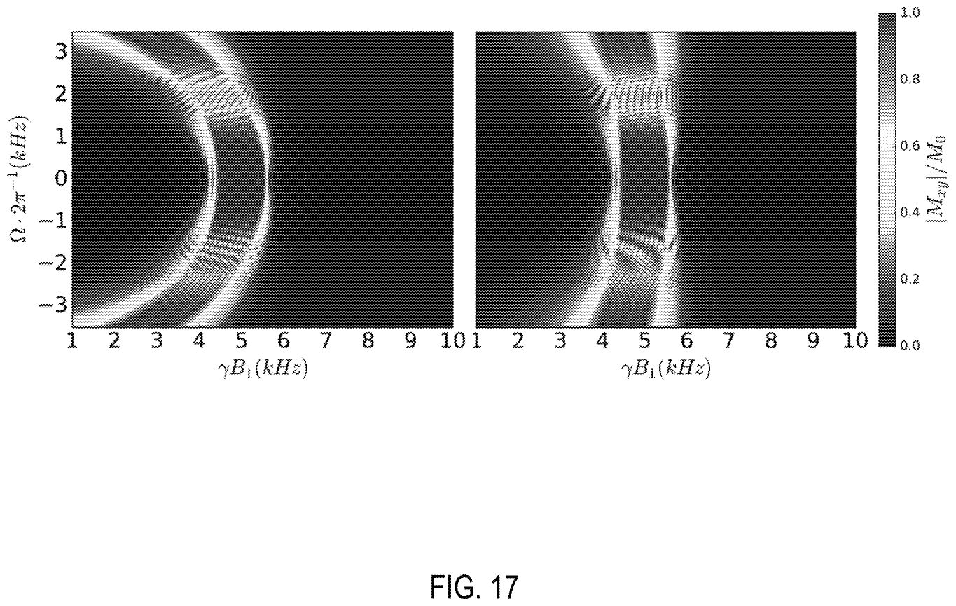

FIG. 17 shows simulation results in which a constant transmit offset of 5 kHz was placed on B̅₂̅(t). The resonance offset modifies the slice's center frequency to produce circular bands, as shown in the left. Rather than hold the center frequency constant, the center frequency is modified as previously described to enable the slice profile to remain largely stable across large resonance offset values, as shown on the right. Ripples are seen where the linear subadiabtic region and the slice profile intersect. The adiabatic pulse has an A=2 kHz.

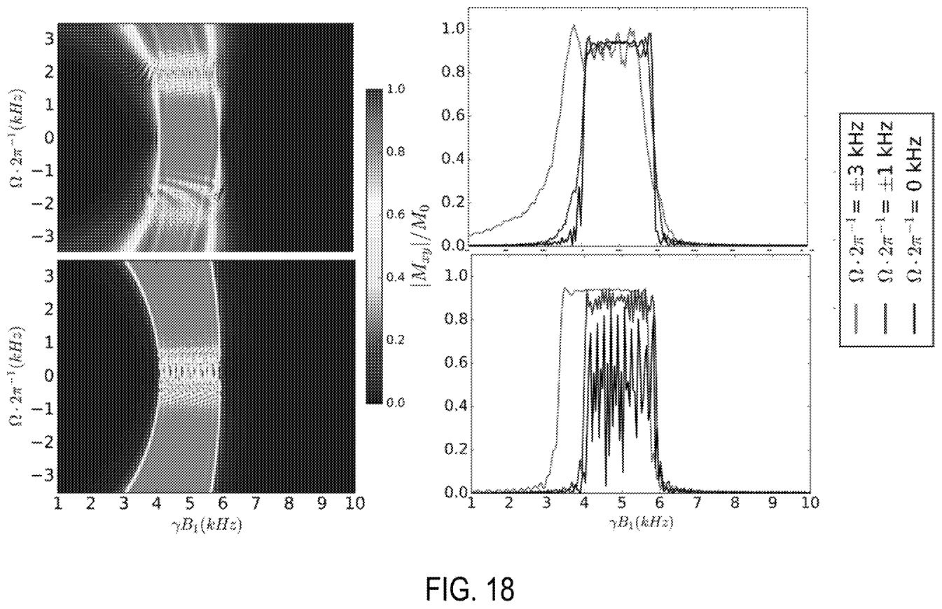

FIGS. 18-21 show example experimental results.

In FIG. 18, a selected slice at a center frequency of 5 kHz for two different B₁(t) functions is shown. B₂(t) was inserted during the middle 50 percent of B₁(t). The pulse sequence in FIG. 9 refocused the spins, and phase cycling was performed using the phase cycle in Table 1. Ripples in the off-resonance profile of the pulse appear where there is an intersection between B₁(t)'s linear subadiabatic region and the slice profile. The B₁(t) for both simulations was described by 2000 pulse elements, had a Tₚ=20 ms, and were HS8 pulses. The top and bottom simulation respectively had an A=2 kHz and A=0.2 kHz. The B₂(t) for both simulations was a truncated 2 ms two-lobe Sinc pulse described by 1000 points. Other experimental parameters include: Δτ₁=10 μs and Δτ₂=1 μs, while τ₁=1 μs and τ₂=10 μs.

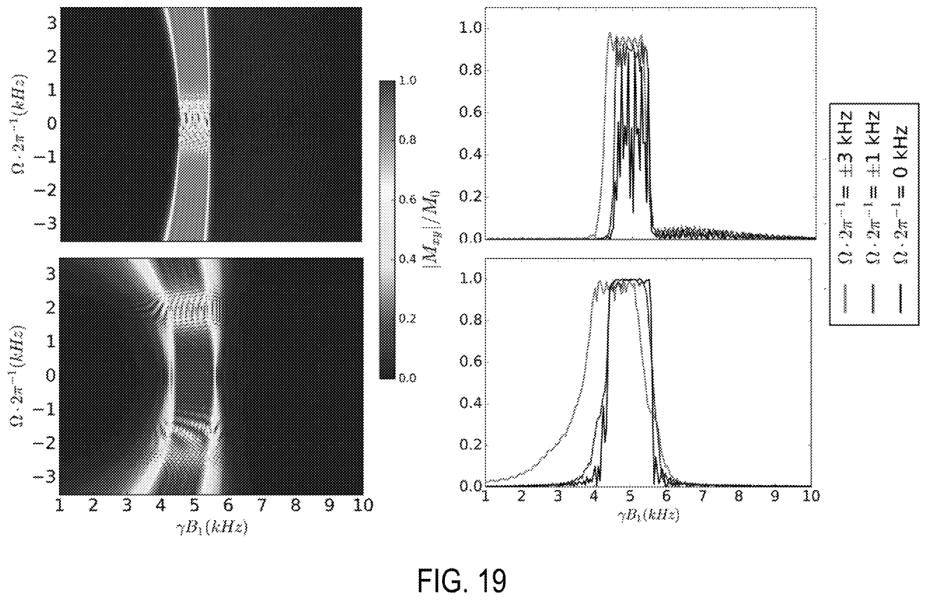

In FIG. 19, a thinner slice with a center frequency of 5 kHz is shown for two different B₁(t) functions. B₂(t) was inserted throughout the entire B₁(t) pulse. The pulse sequence in FIG. 19 refocused the spins, and phase cycling was performed using the phase cycle in Table 1. Ripples in the off-resonance profile of the pulse appear where there is an intersection between B₁(t)'s linear subadiabatic region and the slice profile. The B₁(t) for both simulations was described by 2000 elements, had a Tₚ=20 ms, and were HS8 pulses. The top and bottom simulation respectively had an A=2 kHz and A=0.2 kHz. The B₂(t) for both simulations was a truncated 2 ms two-lobe Sinc pulse described by 1000 segments. Other parameters include: Δτ₁=10 μs, Δτ₂=0.5 μs, τ₁=0.5 μs, and τ₂=10 μs.

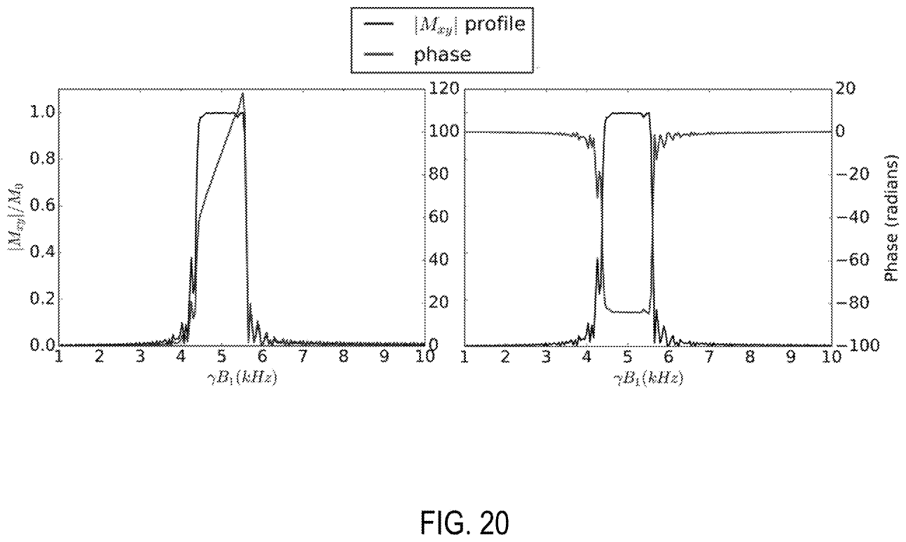

FIG. 20 shows a comparison that demonstrates a slice with no refocusing on the left compared to with refocusing on the right. The pulse sequence in FIG. 19 refocused the spins. The B₁(t) was described by 2000 elements, had a Tₚ=20 ms and an A=2 kHz, and was an HS10 pulse. The B₂(t) was a truncated 2 ms two-lobe Sinc pulse described by 1000 segments. Δτ₁=10 μs and Δτ₂=0.5 μs, while τ₁=0.5 μs and τ₂=10 μs.

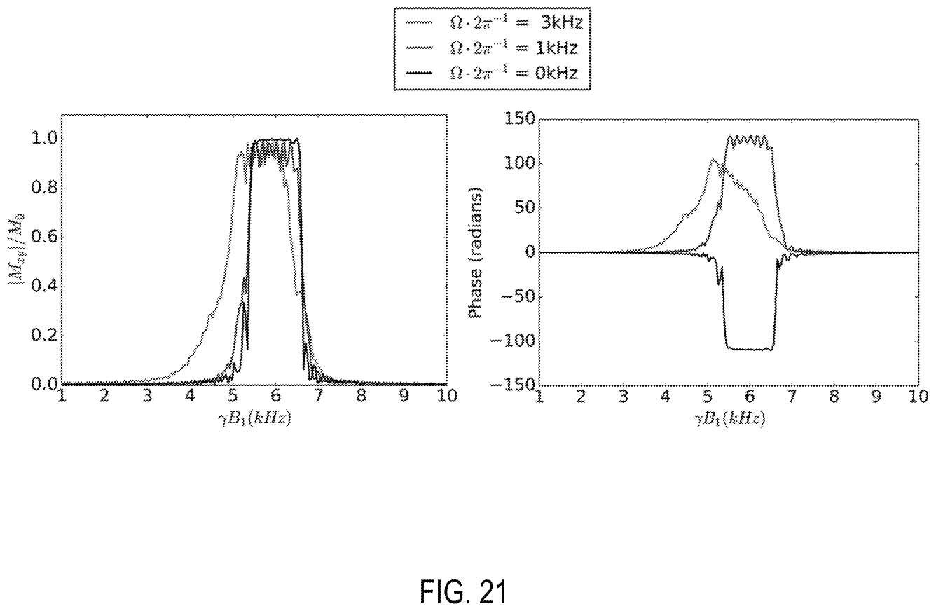

FIG. 21 shows a demonstration of how off-resonance impacts a slice and phase profile of the pulse sequence in FIG. 19. A degradation of the slice profile begins to arise at 3 kHz off-resonance in both the slice and phase profile. The B₁(t) was described by 2000 elements, had a Tₚ=20 ms and an A=2 kHz, and was an HS10 pulses. The B₂(t) was a truncated 2 ms two-lobe Sinc pulse described by 1000 segments. Δτ₁=10 μs and Δτ₂=0.5 μs, while τ₁=0.5 μs and τ₂=10 μs.

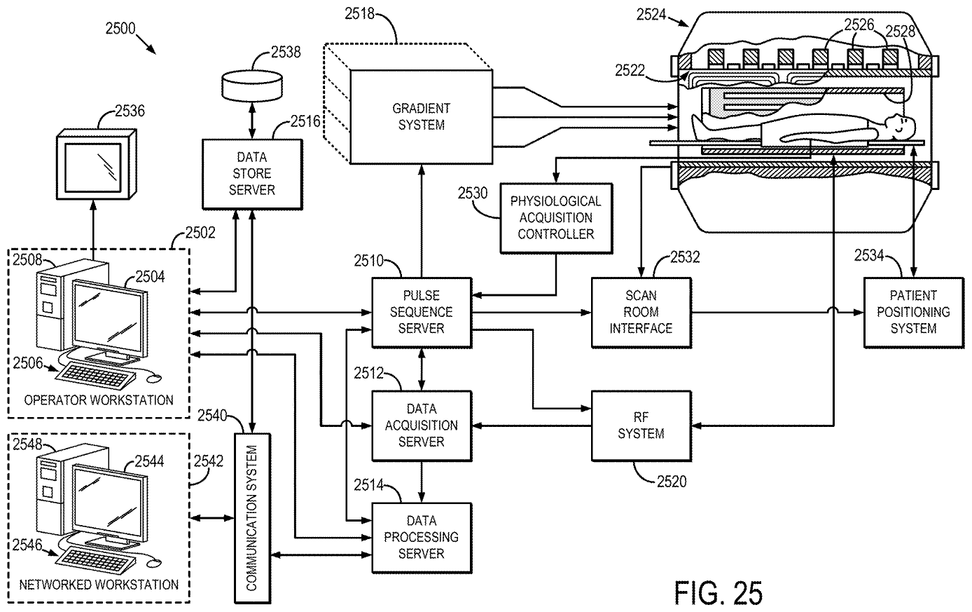

Referring particularly now to FIG. 25, an example of an MRI system 2500 that can implement the methods described here is illustrated. The MRI system 2500 includes an operator workstation 2502 that may include a display 2504, one or more input devices 2506 (e.g., a keyboard, a mouse), and a processor 2508. The processor 2508 may include a commercially available programmable machine running a commercially available operating system. The operator workstation 2502 provides an operator interface that facilitates entering scan parameters into the MRI system 2500. The operator workstation 2502 may be coupled to different servers, including, for example, a pulse sequence server 2510, a data acquisition server 2512, a data processing server 2514, and a data store server 2516. The operator workstation 2502 and the servers 2510, 2512, 2514, and 2516 may be connected via a communication system 2540, which may include wired or wireless network connections.

The pulse sequence server 2510 functions in response to instructions provided by the operator workstation 2502 to operate a gradient system 2518 and a radiofrequency (“RF”) system 2520. Gradient waveforms for performing a prescribed scan are produced and applied to the gradient system 2518, which then excites gradient coils in an assembly 2522 to produce the magnetic field gradients Gₓ, G_{y}, and G_{z} that are used for spatially encoding magnetic resonance signals. The gradient coil assembly 2522 forms part of a magnet assembly 2524 that includes a polarizing magnet 2526 and a whole-body RF coil 2528. In some implementations, spatial encoding can be provided using the RF system 2520 and RF coil 2528 or a separate local RF coil, advantageously eliminating the need for Gₓ, G_{y}, G_{z}, or a combination thereof.

RF waveforms are applied by the RF system 2520 to the RF coil 2528, or a separate local coil to perform the prescribed magnetic resonance pulse sequence. Responsive magnetic resonance signals detected by the RF coil 2528, or a separate local coil, are received by the RF system 2520. The responsive magnetic resonance signals may be amplified, demodulated, filtered, and digitized under direction of commands produced by the pulse sequence server 2510. The RF system 2520 includes an RF transmitter for producing a wide variety of RF pulses used in MRI pulse sequences. The RF transmitter is responsive to the prescribed scan and direction from the pulse sequence server 2510 to produce RF pulses of the desired frequency, phase, and pulse amplitude waveform. The generated RF pulses may be applied to the whole-body RF coil 2528 or to one or more local coils or coil arrays.

The RF system 2520 also includes one or more RF receiver channels. An RF receiver channel includes an RF preamplifier that amplifies the magnetic resonance signal received by the coil 2528 to which it is connected, and a detector that detects and digitizes the I and Q quadrature components of the received magnetic resonance signal. The magnitude of the received magnetic resonance signal may, therefore, be determined at a sampled point by the square root of the sum of the squares of the I and Q components:

$$M = \sqrt{{I}^{2} + {Q}^{2}} ;$$

and the phase of the received magnetic resonance signal may also be determined according to the following relationship:

$$φ = {tan}^{- 1} ( \frac{Q}{I} ) .$$

The pulse sequence server 2510 may receive patient data from a physiological acquisition controller 2530. By way of example, the physiological acquisition controller 2530 may receive signals from a number of different sensors connected to the patient, including electrocardiograph (“ECG”) signals from electrodes, or respiratory signals from a respiratory bellows or other respiratory monitoring devices. These signals may be used by the pulse sequence server 2510 to synchronize, or “gate,” the performance of the scan with the subject's heart beat or respiration.

The pulse sequence server 2510 may also connect to a scan room interface circuit 2532 that receives signals from various sensors associated with the condition of the patient and the magnet system. Through the scan room interface circuit 2532, a patient positioning system 2534 can receive commands to move the patient to desired positions during the scan.

The digitized magnetic resonance signal samples produced by the RF system 2520 are received by the data acquisition server 2512. The data acquisition server 2512 operates in response to instructions downloaded from the operator workstation 2502 to receive the real-time magnetic resonance data and provide buffer storage, so that data is not lost by data overrun. In some scans, the data acquisition server 2512 passes the acquired magnetic resonance data to the data processor server 2514. In scans that require information derived from acquired magnetic resonance data to control the further performance of the scan, the data acquisition server 2512 may be programmed to produce such information and convey it to the pulse sequence server 2510. For example, during pre-scans, magnetic resonance data may be acquired and used to calibrate the pulse sequence performed by the pulse sequence server 2510. As another example, navigator signals may be acquired and used to adjust the operating parameters of the RF system 2520 or the gradient system 2518, or to control the view order in which k-space is sampled. In still another example, the data acquisition server 2512 may also process magnetic resonance signals used to detect the arrival of a contrast agent in a magnetic resonance angiography (“MRA”) scan. For example, the data acquisition server 2512 may acquire magnetic resonance data and processes it in real-time to produce information that is used to control the scan.

The data processing server 2514 receives magnetic resonance data from the data acquisition server 2512 and processes the magnetic resonance data in accordance with instructions provided by the operator workstation 2502. Such processing may include, for example, reconstructing two-dimensional or three-dimensional images by performing a Fourier transformation of raw k-space data, performing other image reconstruction algorithms (e.g., iterative or backprojection reconstruction algorithms), applying filters to raw k-space data or to reconstructed images, generating functional magnetic resonance images, or calculating motion or flow images.

Images reconstructed by the data processing server 2514 are conveyed back to the operator workstation 2502 for storage. Real-time images may be stored in a data base memory cache, from which they may be output to operator display 2502 or a display 2536. Batch mode images or selected real time images may be stored in a host database on disc storage 2538. When such images have been reconstructed and transferred to storage, the data processing server 2514 may notify the data store server 2516 on the operator workstation 2502. The operator workstation 2502 may be used by an operator to archive the images, produce films, or send the images via a network to other facilities.

The MRI system 2500 may also include one or more networked workstations 2542. For example, a networked workstation 2542 may include a display 2544, one or more input devices 2546 (e.g., a keyboard, a mouse), and a processor 2548. The networked workstation 2542 may be located within the same facility as the operator workstation 2502, or in a different facility, such as a different healthcare institution or clinic.

The networked workstation 2542 may gain remote access to the data processing server 2514 or data store server 2516 via the communication system 2540. Accordingly, multiple networked workstations 2542 may have access to the data processing server 2514 and the data store server 2516. In this manner, magnetic resonance data, reconstructed images, or other data may be exchanged between the data processing server 2514 or the data store server 2516 and the networked workstations 2542, such that the data or images may be remotely processed by a networked workstation 2542.

In some configurations, any suitable computer-readable media can be used for storing instructions for performing the functions and/or processes described herein. For example, in some configurations, computer-readable media can be transitory or non-transitory. For example, non-transitory computer-readable media can include media such as magnetic media (e.g., hard disks, floppy disks), optical media (e.g., compact discs, digital video discs, Blu-ray discs), semiconductor media (e.g., RAM, flash memory, EPROM, EEPROM), any suitable media that is not fleeting or devoid of any semblance of permanence during transmission, and/or any suitable tangible media. As another example, transitory computer-readable media can include signals on networks, in wires, conductors, optical fibers, circuits, or any suitable media that is fleeting and devoid of any semblance of permanence during transmission, and/or any suitable intangible media.

As the above description and examples have shown, the present disclosure provides a novel method for MRI that can advantageously achieve slice or slab selection using radiofrequency pulses applied in the presence of a static magnetic field (B₀). In this way, slice or slab selection for an arbitrary flip angle (e.g., low flip angle excitation, 90° excitation, inversion) can be achieved without the need for B₀ gradients in the slice- or slab-selection dimension, potentially reducing the overall cost and complexity of the overall MRI system.

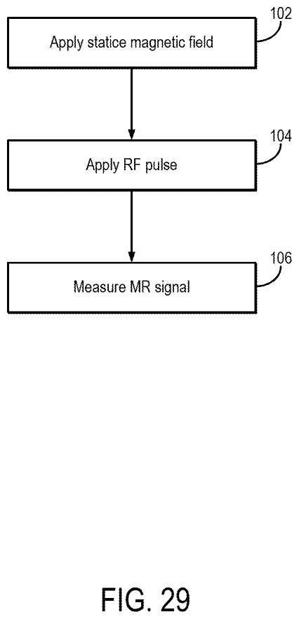

FIG. 29 provides a flowchart illustrating steps of an example process for MRI with spatially selective excitation achieved with B₁-selective pulses. A static magnetic field (B₀) is applied in process block 102. The B₀ field may be applied at a typical, clinical field strength (e.g., 1.5 T, 3 T), high field strength (e.g., 7 T, 9.4 T), or low field strength (e.g., 0.7 T). In some implementations, the B₀ field may be homogeneous or nearly homogeneous across the sample or imaging volume. However, the methods described herein provide selective excitation with resilience to B₀ inhomogeneity, which may allow for a relaxation on the B₀ homogeneity requirements while still providing high-quality imaging. For example, the B₀ field may be applied using a low-cost, portable MRI system (e.g., head-only system).

The RF pulse is applied in process block 104. In general, one or more RF pulses are implemented in the rotating frame using one or more RF coils. The RF pulse may have amplitude- and frequency-modulation patterns that produce two RF field components. The first RF field component provides a temporally varying frequency modulation or a frequency sweep that selectively excites a band of frequencies. The second RF field component provides a spatially varying gradient.

The first RF field component can be applied along a first spatial axis (e.g., x, referred to as B₁ₓ), and the second RF field component can be applied along a second spatial axis (e.g., y, referred to as B_{1y}). These spatial axes can be arbitrarily defined within the MRI system based on the geometry of the RF coils or RF system and do not need to correspond with the scanner axes.

The RF pulse can be designed as an adiabatic pulse, which advantageously provides resilience to B₁ and B₀ inhomogeneity. As non-limiting examples, the RF pulse may include a hyperbolic secant (HSn) pulse, such as an HS1 pulse.

The first RF field component is doubly amplitude modulated, first by a first modulation function or amplitude-modulated shape function, such as HS1, and second by a second modulation function that depends on the phase modulation of the RF pulse. As a non-limiting example, the amplitude-modulated shape function may be defined based on a hyperbolic secant pulse as

$${F}_{1} ( t ) = sech ( \frac{2 β}{{T}_{p}} ( t - \frac{{T}_{p}}{2} ) ) ,$$

which may be scaled by

$${B}_{1 x}^{max} , where {B}_{1 x}^{max}$$

is the maximum of the first RF field component in the second rotating frame

$$( e . g . , {B}_{1 x}^{″} ( t ) ) ,$$

t is time, and Tₚ is the total pulse length of the RF pulse.

The second modulation function is a function of the phase modulation of the RF pulse. For example, the total phase modulation, #ₜₒₜ(t) may be defined based on a hyperbolic secant pulse as φₜₒₜ=φ_{HS1}(t)+φ_{off}(t), where

$${ϕ}_{HS 1} ( t ) = \frac{π R}{2 β} ln ( \frac{{B}_{1 x}^{max}}{{B}_{1 x}^{″} ( t )} ) ,$$

R is the time-bandwidth product of the RF pulse, and φ_{off}(t) is a phase modulation offset that can be used to position the selected slice or slab in space. For example, φ_{off}(t) may be a linear phase ramp (e.g., φ_{off}(t)=2πf_{off}t) that is determined based on an offset f_{off} needed to position the slice in space based on the gradient produced by the second RF field component. In this way, the total phase may be a function of the first RF field component and the second RF field component.

The time-dependent amplitude-modulation of the first field component provides selective excitation by producing a frequency sweep that defines a band of nutation frequencies to select along a spatially-varying gradient produced by the second RF field component. In this way, the second RF field component is applied as a spatially-varying gradient over the object or scanning volume that creates a continuum of nutation or Rabi frequencies. For example, the second RF field component may be applied as a linear or nearly linear gradient.

The RF field that provides B₁-selective excitation can be flexibly applied using several different RF coil or RF system setups. For example, the RF field can be applied using a single coil, where the first and second RF field components are produced as the real and imaginary field components of the RF pulse, respectively. As another example, the RF field can be applied using two RF coils (e.g., surface coils). These coils may be arranged orthogonally or substantially orthogonally (e.g., 80°-110°). In this way, the first RF field component can be generated by the first RF coil while the second RF field component can be generated by the second RF coil. As another example, the RF field can be applied using a parallel transmit RF system with multiple channels.

The RF field can also be flexibly applied using either circularly- or linearly-polarized driving functions. For example, the RF system may include an optional z-coil tuned to the Rabi frequency of interest. This z-coil can be used to create a circularly-polarized field to reduce the overall SAR. In other implementations, a linearly-polarized driving function can be used.

Even more, while the RF pulse may be defined as an adiabatic RF pulse, the RF field can be applied with a sub-adiabatic pulse. Such operation may produce slice- or slab-selection with a varying flip angle. However, this can be corrected using phase cycling or by scaling the pulse amplitude based on a normalized version of the frequency sweep, where the frequency sweep is the temporal derivative of the phase modulation. In this way, the shape function can be scaled by the normalized frequency sweep and phase modulation functions. Phase cycling and scaling can be applied separately or in combination.

The MR signal is measured in process block 106. In some implementations, measurement of the MR signal may include application of a pulse sequence that provides in-plane spatial encoding of the slice or slab selectively excited in process block 104. Such in-plane spatial encoding may be applied using B₀ gradients in one or two dimensions without requiring B₀ gradients in the slice or slab dimension. In other implementations, in-plane spatial encoding in one or more dimensions can be provided with B₁-encoding methods, further reducing or altogether eliminating the need for B₀ gradients.

As used herein in the context of computer implementation, unless otherwise specified or limited, the terms “component,” “system,” “module,” “controller,” “framework,” and the like are intended to encompass part or all of computer-related systems that include hardware, software, a combination of hardware and software, or software in execution. For example, a component may be, but is not limited to being, a processor device, a process being executed (or executable) by a processor device, an object, an executable, a thread of execution, a computer program, or a computer. By way of illustration, both an application running on a computer and the computer can be a component One or more components (or system, module, and so on) may reside within a process or thread of execution, may be localized on one computer, may be distributed between two or more computers or other processor devices, or may be included within another component (or system, module, and so on).

In some implementations, devices or systems disclosed herein can be utilized or installed using methods embodying aspects of the disclosure. Correspondingly, description herein of particular features, capabilities, or intended purposes of a device or system is generally intended to inherently include disclosure of a method of using such features for the intended purposes, a method of implementing such capabilities, and a method of installing disclosed (or otherwise known) components to support these purposes or capabilities. Similarly, unless otherwise indicated or limited, discussion herein of any method of manufacturing or using a particular device or system, including installing the device or system, is intended to inherently include disclosure, as embodiments of the disclosure, of the utilized features and implemented capabilities of such device or system.

As used herein, the phrase “at least one of A, B, and C” means at least one of A, at least one of B, and/or at least one of C, or any one of A, B, or C or combination of A, B, or C. A, B, and C are elements of a list, and A, B, and C may be anything contained in the Specification.

The present disclosure has described one or more preferred embodiments, and it should be appreciated that many equivalents, alternatives, variations, and modifications, aside from those expressly stated, are possible and within the scope of the invention.

1. A method for magnetic resonance imaging of a sample, the method comprising steps of:
a) applying a static magnetic field to the sample;
b) in a presence of the static magnetic field, applying a radiofrequency (RF) pulse, the RF pulse comprising a first RF field component along a first spatial axis and a second RF field component along a second spatial axis, wherein the first RF field component is doubly amplitude modulated using a first modulation function and a second modulation function that is a function of a phase of the RF pulse, and wherein the RF pulse selectively excites a portion of the sample; and
c) measuring a magnetic resonance signal produced by the excited portion of the sample.

2. The method of claim 1, wherein the portion of the sample is at least one of a slice or a slab.

3. The method of claim 1, wherein the RF pulse is adiabatic.

4. The method of claim 1, wherein the first modulation function is a hyperbolic secant (HSn) function.

5. The method of claim 4, wherein the HSn function is an HS1 modulation function.

6. The method of claim 1, wherein the RF pulse is a B₁-insensitive rotation (BIR) pulse.

7. The method of claim 6, wherein the BIR pulse is a BIR-4 pulse.

8. The method of claim 1, wherein the second modulation function is a function of a total phase of the RF field.

9. The method of claim 8, wherein the total phase is a function of the first RF field component and the second RF field component.

10. The method of claim 1, wherein the RF field is applied using a single RF coil, such that the first RF field component is a real component of the RF field generated by the single RF coil and the second RF field component is an imaginary component of the RF field generated by the single RF coil.

11. The method of claim 1, wherein the RF field is applied using at least two RF coils.

12. The method of claim 11, wherein the first RF field component is generated using a first RF coil and the second RF field component is generated using a second RF coil.

13. The method of claim 1, wherein the first RF field component is a temporally varying RF field component and the second RF field component is a spatially varying RF field component.

14. A method for magnetic resonance imaging of a sample, the method comprising steps of:
applying a static magnetic field to the sample; and
in a presence of the static magnetic field, applying an adiabatic radiofrequency pulse to generate a spatially varying radiofrequency magnetic field in a first direction and a temporally varying radiofrequency field in a second direction, the temporally varying radiofrequency field selectively exciting a portion of the sample.

15. The method of claim 14, wherein the first direction is orthogonal to the second direction.

16. The method of claim 14, wherein the spatially varying radiofrequency magnetic field is generated in the first direction by a first radiofrequency coil system, and the temporally varying radiofrequency field is generated in the second direction by a second radiofrequency coil system.

17. The method of claim 14, wherein the spatially varying radiofrequency magnetic field and the temporally varying magnetic field are generated by a single radiofrequency coil system, wherein the spatially varying radiofrequency magnetic field is generated as an imaginary component of the radiofrequency magnetic field generated by the single radiofrequency coil system and the temporally varying radiofrequency field is generated as a real component of the radiofrequency magnetic field generated by the single radiofrequency coil system.

18. The method of claim 17, wherein the single radiofrequency coil system comprises a parallel transmit coil array.

19. The method of claim 14, wherein the temporally varying radiofrequency field is doubly amplitude-modulated.

20. The method of claim 19, wherein the doubly amplitude-modulated radiofrequency field is amplitude-modulated by a first modulation function and amplitude-modulated by a second modulation function based on a phase of the radiofrequency field.

21. The method of claim 20, wherein the first modulation function is a hyperbolic secant.
